(19) United States
(12) Patent Application Publication
(10) Pub. No.: US 2024/0119889 A1
(43) Pub. Date: Apr. 11, 2024

(54) DISPLAY DEVICE

(71) Applicant: Samsung Display Co., LTD., Yongin-si (KR)

(72) Inventors: Yoon Sun CHOI, Yongin-si (KR); Won Suk CHOI, Yongin-si (KR)

(21) Appl. No.: 18/226,846

(22) Filed: Jul. 27, 2023

(30) Foreign Application Priority Data
Oct. 7, 2022 (KR) 10-2022-0128587
Mar. 6, 2023 (KR) 10-2023-0028924

(51) Int. Cl. G09G 3/32; H01L 25/075; H01L 33/62

(52) U.S. Cl. CPC G09G 3/32; H01L 25/0753; H01L 33/62; G09G 2310/0275

(57) ABSTRACT

A display device includes a substrate and a circuit layer. The circuit layer includes pixel drivers; data lines; a first transmission detour line electrically connected to, among the data lines, a first data line and extending in a first direction; and a second transmission detour line adjacent to, among the data lines, a second data line, extending in a second direction, and electrically connected to the first transmission detour line. The first transmission detour line includes a first main stream extending in the first direction between the first data line and the second transmission detour line; a first sub-branch extending in the second direction from the first main stream, and overlapping a part of the first data line; and a second sub-branch extending in the second direction from the first main stream, and overlapping a part of the second transmission detour line.

This application claims priority to Korean Patent Application No. 10-2022-0128587, filed on Oct. 7, 2022, and Korean Patent Application No. 10-2023-0028924, filed on Mar. 6, 2023, and all the benefits accruing therefrom under 35 U.S.C. § 119, the content of which in their entirety is herein incorporated by reference.

### BACKGROUND

### 1. Field

The disclosure relates to a display device.

### 2. Description of the Related Art

With an advance of information-oriented society, more and more demands are placed on display devices for displaying images in various ways. For example, display devices are employed in various electronic devices such as smartphones, digital cameras, laptop computers, navigation devices, and smart televisions.

The display device may include a display panel emitting light for image display and a driver supplying a signal or power for driving the display panel.

The display device may display an image on at least one surface. The display surface of the display device may include a display area in which a plurality of emission areas emitting light for image display is arranged, and a non-display area disposed around the display area.

The display device may include data lines for transmitting data signals to the plurality of emission areas and a display driving circuit for supplying data signals to the data lines.

### SUMMARY

Data supply lines connecting the data lines to the display driving circuit are disposed in the non-display area. Accordingly, when the number of data lines increases to improve resolution, the width for the arrangement of the increased data supply lines increases and, thus, the width of the non-display area may increase.

In this case, the ratio of the display area on the display surface decreases, so that the display quality of the display device may deteriorate. That is, the ratio of the display area on the display surface may have a trade-off relationship with the resolution.

Features of the disclosure provide a display device capable of reducing the width of a non-display area without affecting resolution.

In an embodiment of the disclosure, there is provided a display device which includes a substrate including a main region including a display area in which emission areas are arranged and a non-display area disposed around the display area; a circuit layer disposed on the substrate; and a light-emitting element layer disposed on the circuit layer and including light-emitting elements respectively corresponding to the emission areas. A detour area on a side of the display area includes a detour middle area at a center, a first detour side area parallel to the detour middle area in a first direction and in contact with the non-display area, and a second detour side area disposed between the detour middle area and the first detour side area. The circuit layer includes pixel drivers corresponding to the emission areas and electrically connected to the light-emitting elements of the light-emitting element layer, respectively; data lines extending in a second direction crossing the first direction and transmitting data signals to the pixel drivers; a first transmission detour line electrically connected to, among the data lines, a first data line disposed in the first detour side area and extending in the first direction; and a second transmission detour line adjacent to, among the data lines, a second data line disposed in the second detour side area, extending in the second direction, and electrically connected to the first transmission detour line. The first transmission detour line includes a first main stream extending in the first direction between the first data line and the second transmission detour line; a first sub-branch disposed in the first detour side area, extending in the second direction from the first main stream, and overlapping a part of the first data line; and a second sub-branch disposed in the second detour side area, extending in the second direction from the first main stream, and overlapping a part of the second transmission detour line.

In an embodiment, each of the pixel drivers includes a data connection electrode electrically connected to one of the data lines through a data connection hole. The pixel drivers include a first pixel driver adjacent to the first sub-branch of the first transmission detour line. The first data line includes a first main extension extending in the second direction; a first sub-protrusion adjacent to the first pixel driver, protruding from the first main extension and overlapping the first sub-branch; and a second sub-protrusion adjacent to the first pixel driver, protruding from the first main extension and overlapping the data connection hole of the first pixel driver. The first transmission detour line is electrically connected to the first data line through a first detour connection hole overlapping the first sub-branch and the first sub-protrusion. The first detour connection hole is spaced apart from an intersection between the first main stream of the first transmission detour line and the first main extension of the first data line.

In an embodiment, the pixel drivers further include a second pixel driver disposed in the first detour side area, electrically connected to the first data line, and spaced apart from the first pixel driver. The first data line further includes a third sub-protrusion and a fourth sub-protrusion adjacent to the second pixel driver and protruding from the first main extension. The third sub-protrusion overlaps a first dummy hole. The fourth sub-protrusion overlaps the data connection electrode of the second pixel driver.

In an embodiment, the data lines and the second transmission detour line are disposed on a via layer covering the first transmission detour line and the data connection electrode. The first detour connection hole, the second detour connection hole, and the first dummy hole penetrate the via layer.

In an embodiment, the first dummy hole overlaps a dummy electrode covered with the via layer.

In an embodiment, the pixel drivers further include a third pixel driver disposed in the second detour side area, adjacent to the second sub-branch of the first transmission detour line, electrically connected to the second data line, and disposed parallel to the first pixel driver in the first direction. The second data line includes a second main extension extending in the second direction; a fifth sub-protrusion adjacent to the third pixel driver, protruding from the second main extension, and disposed parallel to the first sub-protrusion of the first data line in the first direction; and a sixth sub-protrusion adjacent to the third pixel driver, protruding from the second main extension, disposed parallel to the second sub-protrusion of the first data line in the first direction, and overlapping the data connection electrode of the third pixel driver. The fifth sub-protrusion overlaps a second dummy hole penetrating the via layer.

In an embodiment, the second transmission detour line includes a third main extension extending in the second direction; a seventh sub-protrusion adjacent to the third pixel driver, protruding from the third main extension, facing the fifth sub-protrusion of the second data line, and overlapping the second sub-branch; and an eighth sub-protrusion adjacent to the third pixel driver, protruding from the third main extension, and facing the sixth sub-protrusion of the second data line. The first transmission detour line is electrically connected to the second transmission detour line through a second detour connection hole overlapping the second sub-branch and the seventh sub-protrusion. The eighth sub-protrusion overlaps a third dummy hole penetrating the via layer.

In an embodiment, the circuit layer further includes a first power supply line and a second power supply line disposed in the non-display area and respectively transmitting a first power and a second power for driving the light-emitting elements; first power auxiliary lines disposed in the display area, extending in the first direction, and electrically connected to the first power supply line; first dummy lines respectively adjacent to the first power auxiliary lines and extending in the first direction; and second dummy lines respectively adjacent to the data lines and extending in the second direction. The first dummy lines include first auxiliary lines electrically connected to the second power supply line, and the first transmission detour line. The second dummy lines include second auxiliary lines electrically connected to the second power supply line, and the second transmission detour line. One of the first auxiliary lines includes a second main stream extending in the first direction; and a third sub-branch extending from the second main stream in the second direction. Each of the second auxiliary lines includes a fourth main extension extending in the second direction; and a ninth sub-protrusion and a tenth sub-protrusion protruding from the fourth main extension to each of the pixel drivers. Some of the ninth sub-protrusions of the second auxiliary lines overlap the third sub-branch. The others of the ninth sub-protrusions of the second auxiliary lines and the tenth sub-protrusions of the second auxiliary lines overlap a fourth dummy hole penetrating the via layer. The first auxiliary lines are electrically connected to the second auxiliary lines through an auxiliary connection hole overlapping the third sub-branch and the ninth sub-protrusion.

In an embodiment, the first dummy hole, the second dummy hole, the third dummy hole, and the fourth dummy hole overlap the dummy electrodes covered with the via layer, respectively.

In an embodiment, the circuit layer has a structure including a semiconductor layer on the substrate; a first conductive layer on a first gate insulating layer covering the semiconductor layer; a second conductive layer on a second gate insulating layer covering the first conductive layer; a third conductive layer on an inter-insulating layer covering the second conductive layer; a fourth conductive layer on a first planarization layer covering the third conductive layer; a fifth conductive layer on a second planarization layer covering the fourth conductive layer; and a third planarization layer covering the fifth conductive layer. The fourth conductive layer includes the first power auxiliary lines, the first dummy lines, and the dummy electrodes. The fifth conductive layer includes the data lines and the second dummy lines. The via layer includes the second planarization layer.

In an embodiment, the substrate further includes a hole area surrounded by the display area. The data lines further include a hole intersection data line intersecting the hole area. The hole intersection data line includes a first hole adjacent portion disposed adjacent to a side of the hole area in the second direction, and a second hole adjacent portion disposed adjacent to an opposite side of the hole area in the second direction. The first dummy lines further include a first hole detour line electrically connected to the first hole adjacent portion of the hole intersection data line; and a second hole detour line electrically connected to the second hole adjacent portion of the hole intersection data line. The second dummy lines further include a third hole detour line electrically connecting the first hole detour line and the second transmission detour line. The first hole detour line includes a third main stream extending in the first direction between the first hole adjacent portion and the third hole detour line; a fourth sub-branch extending from the third main stream in the second direction and overlapping a part of the first hole adjacent portion; and a fifth sub-branch extending from the third main stream in the second direction and overlapping a part of the third hole detour line.

In an embodiment, the second hole detour line includes a fourth main stream extending in the first direction between the second hole adjacent portion and the third hole detour line; a sixth sub-branch extending from the fourth main stream in the second direction and overlapping a part of the third hole detour line; and a seventh sub-branch extending from the fourth main stream in the second direction and overlapping a part of the second hole adjacent portion.

In an embodiment, the display device further includes a display driving circuit disposed in a sub-region protruding in the second direction from a side of the main region of the substrate and outputting a data signal of each of the data lines. The circuit layer further includes data supply lines disposed in the non-display area and the sub-region, electrically connected to output terminals of the display driving circuit, respectively, and transmitting the data signal of each of the data lines to the display area. Among the data supply lines, a first data supply line transmitting a data signal of the first data line is connected to the second transmission detour line. Among the data supply lines, a second data supply line transmitting a data signal of the second data line is connected to the second data line.

In an embodiment, the first main stream of the first transmission detour line is disposed closer to the first sub-protrusion, between the first sub-protrusion and the second sub-protrusion of the first data line, in the second direction.

In an embodiment, the first main stream of the first transmission detour line is disposed between the first sub-protrusion and the second sub-protrusion of the first data line in the second direction.

In an embodiment of the disclosure, there is provided a display device which includes a substrate including a main region including a display area in which emission areas are arranged and a non-display area disposed around the display area, and a sub-region protruding from a side of the main region; a circuit layer disposed on the substrate and including pixel drivers respectively corresponding to the emission areas; and a light-emitting element layer disposed on the circuit layer and including light-emitting elements respectively corresponding to the emission areas. The circuit layer includes pixel drivers respectively corresponding to the emission areas and electrically connected to the light-emitting elements of the light-emitting element layer; data lines transmitting data signals to the pixel drivers; first dummy lines extending in a first direction crossing the data lines; and second dummy lines extending in a second direction parallel to the data lines and respectively adjacent to the data lines. The data lines and the second dummy lines are disposed on a via layer covering the first dummy lines. One of the pixel drivers is adjacent to one of the data lines and one of the second dummy lines. Each of the one of the data line and the one of the second dummy lines includes a main extension extending in the second direction; and a pair of sub-protrusions protruding from the main extension, adjacent to the one of the pixel drivers, and overlapping via holes penetrating the via layer.

In an embodiment, in the display area, a detour area adjacent to the sub-region includes a detour middle area disposed at a center in the first direction, a first detour side area parallel to the detour middle area in the first direction and in contact with the non-display area, and a second detour side area disposed between the detour middle area and the first detour side area. The data lines include a first data line disposed in the first detour side area and a second data line disposed in the second detour side area. The first dummy lines include a first transmission detour line electrically connected to the first data line. The second dummy lines include a second transmission detour line adjacent to the second data line and electrically connected to the first transmission detour line. The first transmission detour line includes a first main stream extending in the first direction between the first data line and the second transmission detour line; a first sub-branch disposed in the first detour side area, extending in the second direction from the first main stream, and overlapping a part of the first data line; and a second sub-branch disposed in the second detour side area, extending in the second direction from the first main stream, and overlapping a part of the second transmission detour line.

In an embodiment, the circuit layer further includes a first power supply line and a second power supply line disposed in the non-display area and respectively transmitting a first power and a second power for driving the light-emitting elements; and first power auxiliary lines disposed in the display area, extending in the first direction, respectively adjacent to the first dummy lines, and electrically connected to the first power supply line. The first dummy lines include first auxiliary lines electrically connected to the second power supply line, and the first transmission detour line. The second dummy lines include second auxiliary lines electrically connected to the second power supply line, and the second transmission detour line. One of the first auxiliary lines includes a second main stream extending in the first direction; and a third sub-branch extending from the second main stream in the second direction and overlapping a part of one of the second auxiliary lines.

In an embodiment, each of the pixel drivers includes a data connection electrode electrically connected to one of the data lines through a data connection hole. Among the via holes, remaining via holes except some of the via holes overlapping the data connection electrode, the first sub-branch, the second sub-branch, and the third sub-branch overlap dummy electrodes covered with the via layer, respectively.

In an embodiment, the substrate further includes a hole area surrounded by the display area. The data lines further include a hole intersection data line intersecting the hole area. The hole intersection data line includes a first hole adjacent portion disposed adjacent to a side of the hole area in the second direction, and a second hole adjacent portion disposed adjacent to an opposite side of the hole area in the second direction. The first dummy lines further include a first hole detour line electrically connected to the first hole adjacent portion of the hole intersection data line; and a second hole detour line electrically connected to the second hole adjacent portion of the hole intersection data line. The second dummy lines further include a third hole detour line electrically connecting the first hole detour line and the second transmission detour line. The first hole detour line includes a third main stream extending in the first direction between the first hole adjacent portion and the third hole detour line; a fourth sub-branch extending from the third main stream in the second direction and overlapping a part of the first hole adjacent portion; and a fifth sub-branch extending from the third main stream in the second direction and overlapping a part of the third hole detour line.

In an embodiment, the second hole detour line includes A fourth main stream extending in the first direction between the second hole adjacent portion and the third hole detour line; a sixth sub-branch extending from the fourth main stream in the second direction and overlapping a part of the third hole detour line; and a seventh sub-branch extending from the fourth main stream in the second direction and overlapping a part of the second hole adjacent portion.

In an embodiment, the pair of sub-protrusions includes a first sub-protrusion and a second sub-protrusion, and the first main stream of the first transmission detour line is disposed closer to the first sub-protrusion, between the first sub-protrusion and the second sub-protrusion of the first data line, in the second direction.

In an embodiment, the pair of sub-protrusions includes a first sub-protrusion and a second sub-protrusion, and the first main stream of the first transmission detour line is disposed between the first sub-protrusion and the second sub-protrusion of the first data line in the second direction.

In an embodiment, a display device in an embodiment includes a substrate having a main region including a display area and a non-display area disposed around the display area; a circuit layer disposed on the substrate; and a light-emitting element layer disposed on the circuit layer.

In an embodiment, a detour area on a side of the display area of the substrate includes a detour middle area at the center; a first detour side area parallel to the detour middle area in a first direction and in contact with the non-display area; and a second detour side area disposed between the detour middle area and the first detour side area.

In an embodiment, the circuit layer includes pixel drivers respectively corresponding to emission areas; data lines transmitting data signals to the pixel drivers; a first transmission detour line electrically connected to, among the data lines, a first data line disposed in the first detour side area and extending in the first direction; and a second transmission detour line adjacent to, among the data lines, a second data line disposed in the second detour side area, extending in a second direction, and electrically connected to the first transmission detour line.

In an embodiment, the data signal of each of the data lines may be supplied by a display driving circuit disposed in a sub-region protruding from a side of the main region of the substrate. To this end, the circuit layer may include data supply lines respectively connected to output terminals of the display driving circuit, disposed in the non-display area, and extending to the display area.

In addition, a part of the non-display area in contact with the first detour side area may include a shape bent along a point where two sides of the edge of the substrate meet.

In an embodiment, the first data line of the first detour side area adjacent to the non-display area may be electrically connected to the second transmission detour line of the second detour side area adjacent to the detour middle area through the first transmission detour line extending in the first direction.

In addition, among the data supply lines, a first data supply line serving to transmit the data signal of the first data line may be electrically connected to the second transmission detour line of the second detour side area. Accordingly, the first data line may be electrically connected to the first data supply line through the first transmission detour line and the second transmission detour line.

In other words, even when the first data supply line extends to the second detour side area instead of the first detour side area, it may still be electrically connected to the first data line of the first detour side area through the first transmission detour line and the second transmission detour line.

Accordingly, the portion of the non-display area adjacent to the first detour side area and including the bent shape may have a smaller width because the first data supply line is not disposed therein.

Accordingly, the width of the non-display area may be reduced without reducing the number of the data lines.

In an embodiment, the first transmission detour line includes a first main stream extending in the first direction between the first data line and the second transmission detour line; a first sub-branch disposed in the first detour side area, extending in the second direction from the first main stream, and overlapping a part of the first data line; and a second sub-branch disposed in the second detour side area, extending in the second direction from the first main stream, and overlapping a part of the second transmission detour line.

In other words, in the first transmission detour line, the first main stream extending in the first direction between the first data line and the second transmission detour line does not overlap the first data line and the second transmission detour line.

In addition, the first transmission detour line may be electrically connected to the first data line and the second transmission detour line through the first and second sub-branches extending in the second direction. Accordingly, the overlapping areas between the first transmission detour line and each of the first data line and the second transmission detour line may be spaced apart from ends of the first main stream.

Therefore, the visibility of the ends of the first main stream may be prevented from being increased by a first detour connection hole and a second detour connection hole defined in the overlapping areas between the first transmission detour line and each of the first data line and the second transmission detour line.

Therefore, since the visibility of the first and second transmission detour lines for reducing the width of the non-display area may be prevented from being increased, deterioration in display quality of the display device due to the presence of the first and second transmission detour lines may be reduced.

The effects of the disclosure are not limited to the aforementioned effects, and various other effects are included in the specification

### BRIEF DESCRIPTION OF THE DRAWINGS

The above and other features and features of the disclosure will become more apparent by describing in detail embodiments thereof with reference to the attached drawings, in which:

FIG. 1 is a perspective view illustrating an embodiment of a display device;

FIG. 2 is a plan view illustrating the display device of FIG. 1;

FIG. 3 is a cross-sectional view showing a plane taken along line A-A′ of FIG. 2;

FIG. 4 is a plan view illustrating the main region and the sub-region of the display device of FIG. 1;

FIG. 5 is a layout diagram illustrating part B of FIG. 4;

FIG. 6 is a layout diagram illustrating the data lines, the first dummy lines, the second dummy lines, and the first power auxiliary lines in part C of FIG. 4;

FIG. 7 is a cross-sectional view showing a plane taken along line I-I′ of FIG. 6;

FIG. 8 is a cross-sectional view showing a plane taken along line J-J′ of FIG. 6;

FIG. 9 is a layout diagram illustrating data lines, first dummy lines, second dummy lines, and first power auxiliary lines in part D of FIG. 4;

FIG. 10 is a layout diagram illustrating data lines, first dummy lines, second dummy lines, and first power auxiliary lines in part E of FIG. 4;

FIG. 11 is an equivalent circuit diagram showing one embodiment of one pixel driver of the circuit layer of FIG. 3;

FIG. 12 is a plan view showing part G of FIG. 5 according to a first embodiment;

FIG. 13 is a plan view illustrating a semiconductor layer, a first conductive layer, a second conductive layer, and a third conductive layer in the plan view of FIG. 12;

FIG. 14 is a plan view showing a fourth conductive layer and a fifth conductive layer in the plan view of FIG. 12;

FIG. 15 is a cross-sectional view taken along line K-K′ of FIG. 12;

FIG. 16 is a plan view showing a fourth conductive layer and a fifth conductive layer in part H of FIG. 5 according to the first embodiment;

FIG. 17 is a plan view showing a fourth conductive layer and a fifth conductive layer in part G of FIG. 5 according to a second embodiment;

FIG. 18 is a plan view showing a fourth conductive layer and a fifth conductive layer in part G of FIG. 5 according to a third embodiment;

FIG. 19 is a layout diagram showing part F of FIG. 4 according to a fourth embodiment;

FIG. 20 is a layout diagram showing data lines, first dummy lines, and second dummy lines in a part of each of a first hole vicinity side area and a second hole vicinity side area of FIG. 19; and

FIG. 21 is a cross-sectional view showing a plane taken along line L-L′ of FIG. 21.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the disclosure will be described in detail with reference to the accompanying drawings.

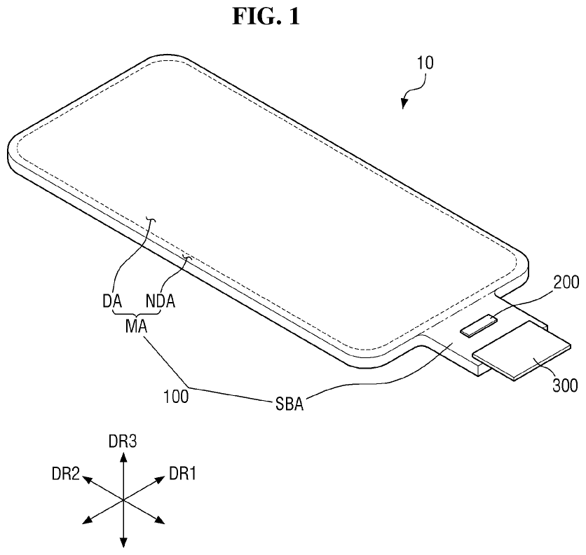

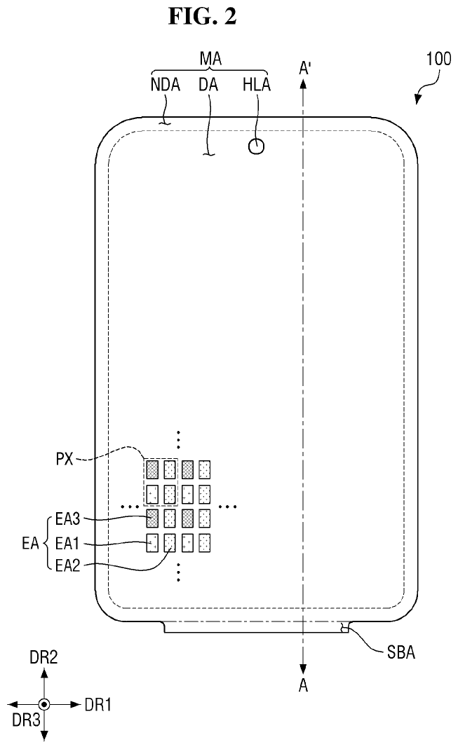

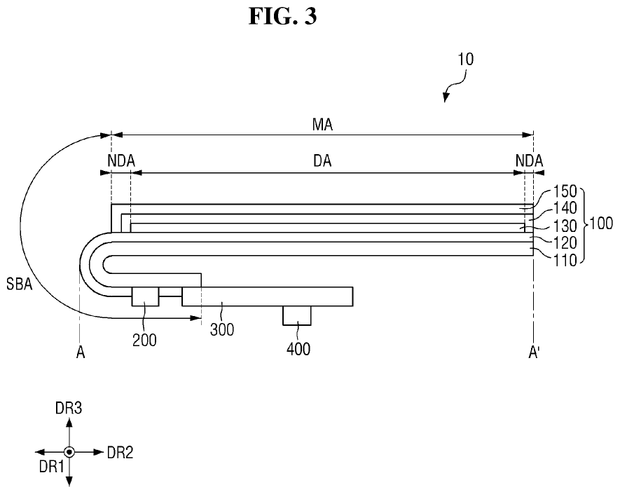

FIG. 1 is a perspective view illustrating an embodiment of a display device. FIG. 2 is a plan view illustrating the display device of FIG. 1. FIG. 3 is a cross-sectional view showing a plane taken along line A-A′ of FIG. 2.

Referring to FIG. 1, a display device 10 is a device for displaying a moving image or a still image. The display device 10 may be used as a display screen of various devices, such as a television, a laptop computer, a monitor, a billboard and an Internet-of-Things (“IoT”) device, as well as portable electronic devices such as a mobile phone, a smartphone, a tablet personal computer (“PC”), a smart watch, a watch phone, a mobile communication terminal, an electronic notebook, an electronic book, a portable multimedia player (“PMP”), a navigation device and an ultra-mobile PC (“UMPC”).

The display device 10 may be a light-emitting display device such as an organic light-emitting display using an organic light-emitting diode, a quantum dot light-emitting display including a quantum dot light-emitting layer, an inorganic light-emitting display including an inorganic semiconductor, and a micro light-emitting display using a micro or nano light-emitting diode (“LED”). In the following description, it is assumed that the display device 10 is an organic light-emitting display device. However, the disclosure is not limited thereto, and may be applied to a display device including an organic insulating material, an organic light-emitting material, and a metal material.

The display device 10 may be formed to be flat, but is not limited thereto. In an embodiment, the display device 10 may include a curved portion formed at left and right ends and having a constant curvature or a varying curvature, for example. In addition, the display device 10 may be formed flexibly so that it may be curved, bent, folded, or rolled.

As shown in FIG. 1, the display device 10 may include a display panel 100, a display driving circuit 200, and a circuit board 300.

The display panel 100 has a main region MA including a display area DA for emitting light for image display and a non-display area NDA as a peripheral region around the display area DA.

Referring to FIG. 2, the display panel 100 of the display device 10 may include the main region MA and a sub-region SBA protruding from one side of the main region MA.

The main region MA may include the display area DA at the center and the non-display area NDA surrounding the display area DA.

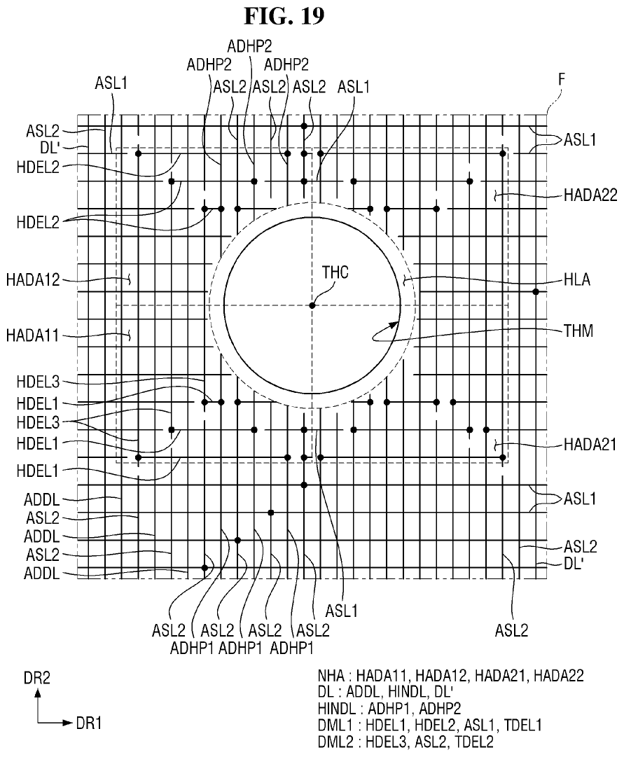

Besides, in some embodiments, the main region MA may further include a hole area HLA surrounded by the display area DA. A display device according to a fourth embodiment including the hole area HLA will be described later with reference to FIGS. 19 to 21.

The sub-region SBA may be a region protruding from the non-display area NDA of the main region MA to one side in the second direction DR2.

Since a part of the sub-region SBA is transformed to be bent, another part of the sub-region SBA may be disposed on the rear surface of the display panel 100.

FIG. 2 illustrates a case in which a part of the sub-region SBA is bent.

A plurality of emission areas EA emitting light with respective luminances are arranged in the display area DA.

The display area DA may, in a plan view, be formed in a quadrangular shape, e.g., a rectangular shape having short sides in a first direction DR1 and long sides in a second direction DR2 crossing the first direction DR1. The corner where the short side in the first direction DR1 and the long side in the second direction DR2 meet may be rounded to have a predetermined curvature or may be right-angled. The planar shape of the display area DA is not limited to the quadrangular shape, e.g., the rectangular shape, and may be formed in another polygonal shape, a circular shape or an elliptical shape.

The display area DA may occupy most of the main region MA. The display area DA may be disposed at the center of the main region MA.

The display area DA may include the plurality of emission areas EA arranged side by side. In addition, the display area DA may further include a non-emission area which is a separation region between the plurality of emission areas EA.

The plurality of emission areas EA may be arranged side by side in the first direction DR1 and the second direction DR2.

Each of the plurality of emission areas EA may have a rhombus planar shape or a quadrangular, e.g., a rectangular planar shape. However, this is only an illustrative embodiment, and the planar shape of the plurality of emission areas EA in an embodiment is not limited to that illustrated in FIG. 2. That is, the plurality of emission areas EA may have a polygonal shape such as a rhombus shape or a hexagonal shape other than a quadrangular shape, e.g., a rectangular shape, a circular shape, or an elliptical shape in a plan view.

The plurality of emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

In an embodiment, the first color may be red having a wavelength band of approximately 600 nanometers (mu) to approximately 750 nm, for example. The second color may be green having a wavelength band of approximately 480 nm to approximately 560 nm, for example. The third color may be blue having a wavelength band of approximately 370 nm to approximately 460 mu.

As illustrated in FIG. 2, the first emission areas EA1 and the third emission areas EA3 may be alternately arranged in at least one of the first direction DR1 and the second direction DR2. Further, the second emission areas EA2 may be arranged side by side in at least one of the first direction DR1 and the second direction DR2.

A plurality of pixels PX displaying respective luminances and colors may include the plurality of emission areas EA.

Each of the plurality of pixels PX may be a basic unit for displaying various colors including white with a predetermined luminance.

Each of the plurality of pixels PX may include at least one first emission area EA1, at least one second emission area EA2, and at least one third emission area EA3 that are adjacent to each other. Accordingly, each of the plurality of pixels PX may display a luminance and a color obtained by mixing lights emitted from at least one first emission area EA1, at least one second emission area EA2, and at least one third emission area EA3 that are adjacent to each other.

Although FIG. 2 illustrates a case in which the plurality of emission areas EA has the same area, this is only an illustrative embodiment. That is, in another embodiment the third emission area EA3 may have the largest area and the second emission area EA2 may have the smallest area.

Further, although FIG. 2 illustrates a case in which the plurality of emission areas EA is arranged side by side in the first direction DR1 and the second direction DR2, this is only an illustrative embodiment. In another embodiment the second emission areas EA2 may be adjacent to the first emission area EA1 and the third emission area EA3 in a diagonal direction intersecting the first direction DR1 and the second direction DR2.

Referring to FIG. 3, the display panel 100 of the display device 10 includes a substrate 110 having the main region MA including the display area DA in which the emission areas EA are arranged and the non-display area NDA disposed around the display area DA, a circuit layer 120 disposed on the substrate 110, and a light-emitting element layer 130 disposed on the circuit layer 120.

The substrate 110 may further include the sub-region SBA protruding from one side of the main region MA.

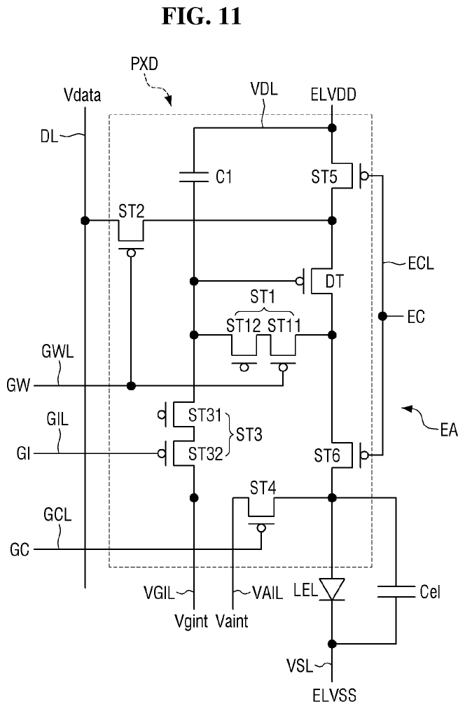

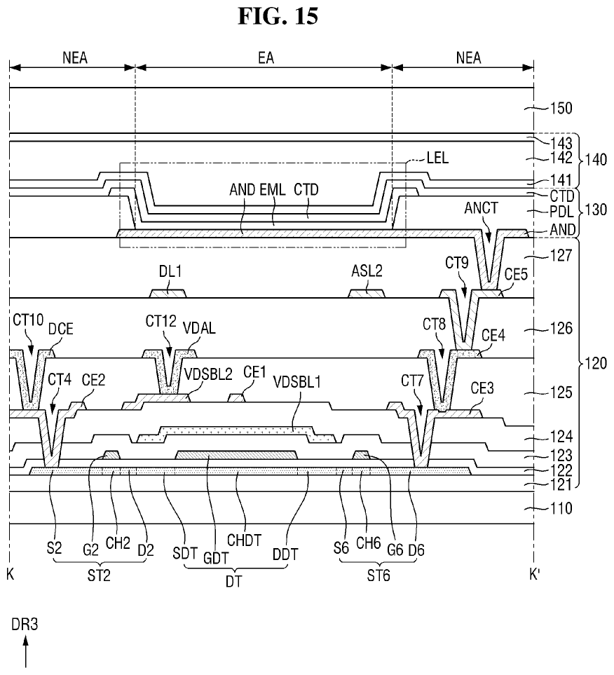

The light-emitting element layer 130 includes light-emitting elements LEL (refer to FIGS. 11 and 15) corresponding to the emission areas EA, respectively.

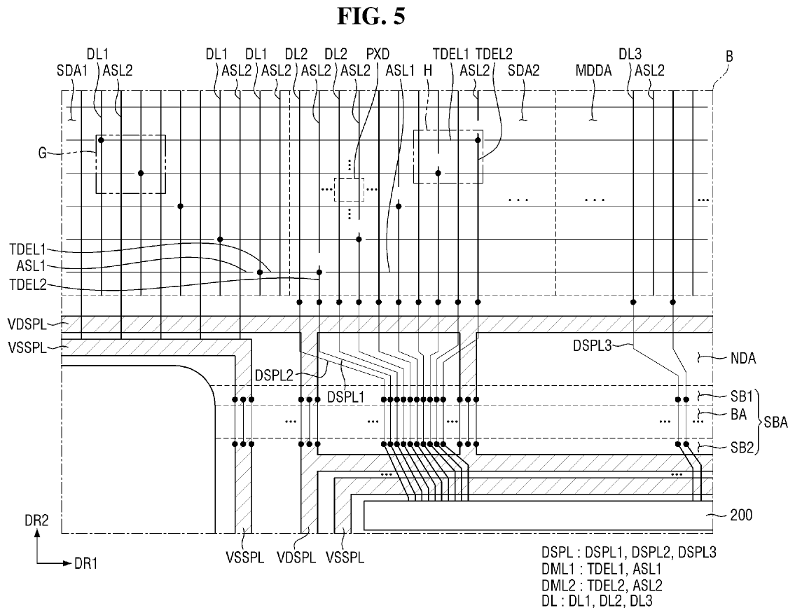

The circuit layer 120 includes pixel drivers PXD (refer to FIGS. 5, 6, and 11) corresponding to the emission areas EA and electrically connected to the light-emitting elements LEL of the light-emitting element layer 130, respectively, and data lines DL (refer to FIGS. 5, 6, and 11) extending in the second direction DR2 and transmitting data signals Vdata (refer to FIG. 11) to the pixel drivers PXD.

The display device 10 may further include the display driving circuit 200 disposed in the sub-region SBA of the substrate 110. The display driving circuit 200 may output the data signals of the data lines DL.

The circuit layer 120 may further include data supply lines DSPL (refer to FIG. 5) disposed in the non-display area NDA and the sub-region SBA, electrically connected to output terminals of the display driving circuit 200, respectively, and serving to transmit the data signal Vdata of each of the data lines DL to the display area DA.

The display driving circuit 200 may be provided as an integrated circuit (“IC”) and disposed (e.g., mounted) on a second sub-region SB2 of the substrate 110 by a chip on glass (“COG”) method, a chip on plastic (“COP”) method, or an ultrasonic bonding method. However, this is only an illustrative embodiment, and the arrangement of the display driving circuit 200 is not limited to that illustrated in FIG. 3.

In an embodiment, the display driving circuit 200 may be attached onto the circuit board 300 by a chip on film (“COF”) method, for example.

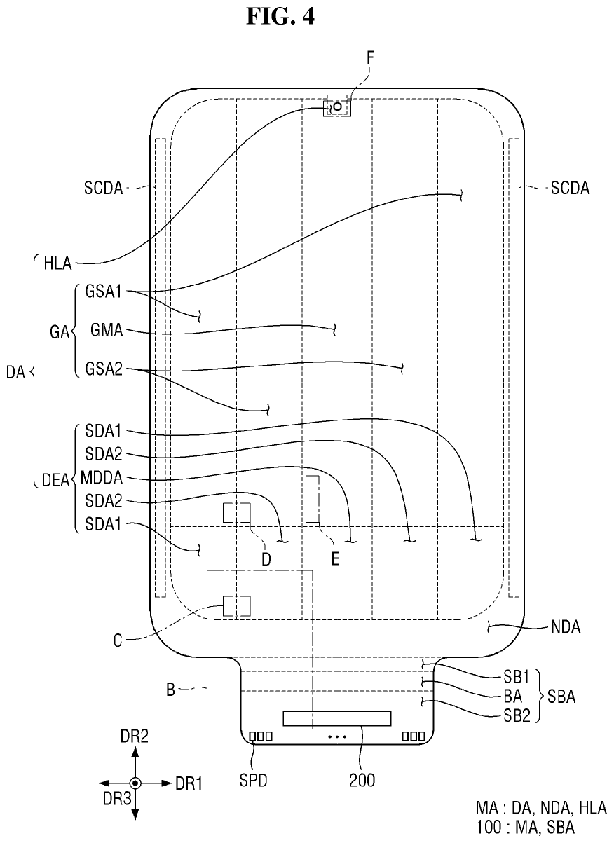

The circuit board 300 may be bonded to signal pads SPD (refer to FIG. 4) disposed in the sub-region SBA of the substrate 110.

In an embodiment, the circuit board 300 may be attached to and electrically connected to the signal pads SPD (refer to FIG. 4) of the sub-region SBA using a low-resistance high-reliability material such as SAP or an anisotropic conductive film, for example.

The pixel drivers PXD of the display area DA and the display driving circuit 200 may receive digital video data, timing signals, and driving voltages from the circuit board 300.

The circuit board 300 may be a flexible printed circuit board, a printed circuit board, or a flexible film such as a COF.

In addition, the display panel 100 of the display device 10 may further include an encapsulation layer 140 covering the light-emitting element layer 130, and a sensor electrode layer 150 disposed on the encapsulation layer 140.

The substrate 110 may include or consist of an insulating material such as a polymer resin. In an embodiment, the substrate 110 may include or consist of polyimide, for example. The substrate 110 may be a flexible substrate which may be bent, folded or rolled.

In an alternative embodiment, the substrate 110 may include or consist of an insulating material such as glass or the like.

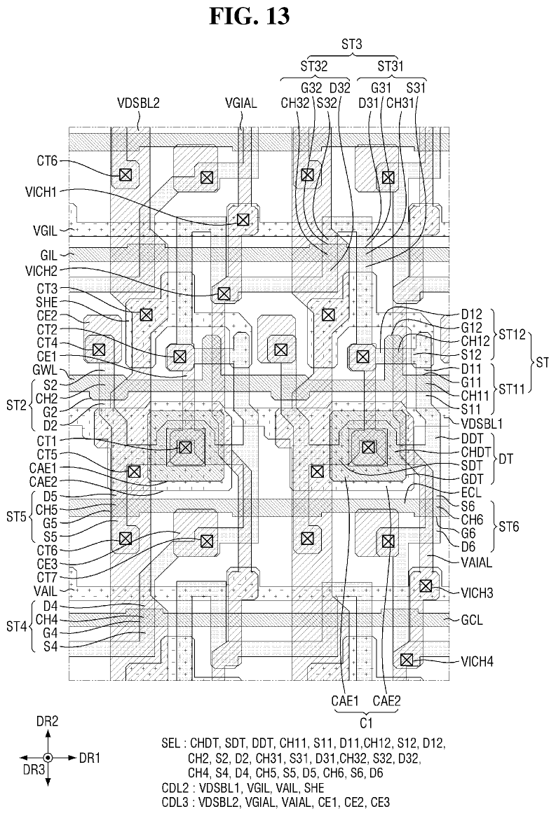

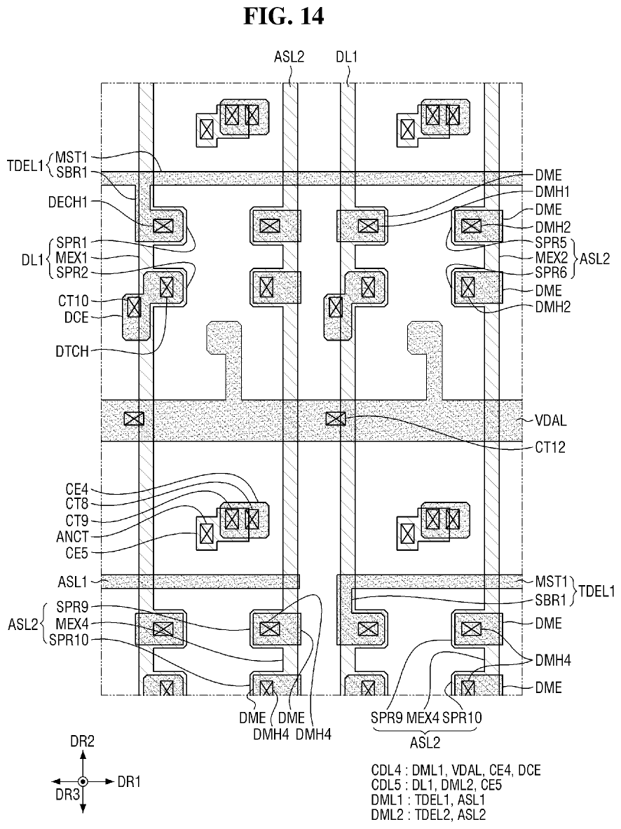

As will be described later with reference to FIG. 15, the circuit layer 120 may have a structure including a semiconductor layer SEL (refer to FIG. 13) on the substrate 110, a first conductive layer CDL1 (refer to FIG. 13) on a first gate insulating layer 122 covering the semiconductor layer SEL, a second conductive layer CDL2 (refer to FIG. 13) on a second gate insulating layer 123 covering the first conductive layer CDL1, a third conductive layer CDL3 (refer to FIG. 13) on an inter-insulating layer 124 covering the second conductive layer CDL2, a fourth conductive layer CDL4 (refer to FIG. 14) on a first planarization layer 125 covering the third conductive layer CDL3, a fifth conductive layer CDL5 (refer to FIG. 14) on a second planarization layer 126 covering the fourth conductive layer CDL4, and a third planarization layer 127 covering the fifth conductive layer CDL5.

The encapsulation layer 140 is disposed on the circuit layer 120, corresponds to the main region MA, and covers the light-emitting element layer 130.

The encapsulation layer 140 may include a structure in which two or more inorganic layers and at least one organic layer are alternately stacked on the light-emitting element layer 130.

The sensor electrode layer 150 may be disposed on the encapsulation layer 140 and may correspond to the main region MA. The sensor electrode layer 150 may include touch electrodes for sensing a touch of a person or an object.

In addition, the display device 10 may further include a cover window (not shown) disposed on the sensor electrode layer 150. The cover window may be attached to the sensor electrode layer 150 by a transparent adhesive member such as an optically clear adhesive (“OCA”) film or an optically clear resin (“OCR”). The cover window may include or consist of an inorganic material such as glass, or an organic material such as plastic or a polymer material. Due to the cover window, the sensor electrode layer 150, the encapsulation layer 140, the light-emitting element layer 130, and the circuit layer 120 may be protected from electrical and physical impact on the display surface.

In addition, the display device 10 may further include an anti-reflection member (not shown) disposed between the sensor electrode layer 150 and the cover window. The anti-reflection member may be a polarizing film or a color filter. The anti-reflection member blocks external light reflected from the sensor electrode layer 150, the encapsulation layer 140, the light-emitting element layer 130, the circuit layer 120, and the interfaces thereof, so that it is possible to prevent a decrease in visibility of an image in the display device 10.

The display device 10 may further include a touch driving circuit 400 for driving the sensor electrode layer 150.

The touch driving circuit 400 may be provided as an IC. The touch driving circuit 400 may be electrically connected to the sensor electrode layer 150 while being disposed (e.g., mounted) on the circuit board 300.

In an alternative embodiment, similarly to the display driving circuit 200, the touch driving circuit 400 may be disposed (e.g., mounted) on the sub-region SBA of the substrate 110.

The touch driving circuit 400 may apply a touch driving signal to a plurality of driving electrodes provided on the sensor electrode layer 150, receive a touch sensing signal of each of a plurality of touch nodes through a plurality of sensing electrodes, and sense a charge change amount of mutual capacitance based on the touch sensing signal.

That is, the touch driving circuit 400 may determine whether the user's touch has been made, whether the user is in proximity, and so forth, according to the touch sensing signals of each of the plurality of touch nodes. The user's touch refers to a direct contact of an object such as a pen or a user's finger with the front surface of the display device 10. The user's being in proximity means that an object such as a pen or a user's finger is disposed away from the front surface of the display device 10, such as hovering.

FIG. 4 is a plan view illustrating the main region and the sub-region of the display device of FIG. 1.

Referring to FIG. 4, the display panel 100 of the display device 10 in an embodiment includes the main region MA including the display area DA and the non-display area NDA, and the sub-region SBA protruding from one side of the main region MA.

The display area DA includes the emission areas EA arranged in the first direction DR1 and the second direction DR2. In addition, the display area DA may further include a non-emission area NEA (refer to FIG. 15) which is a separation region between the emission areas EA.

The display area DA may include a detour area DEA, which is a portion on one side in the second direction DR2 relatively adjacent to the sub-region SBA, and a general area GA, which is the remaining portion except the detour area DEA.

The detour area DEA includes a detour middle area MDDA disposed at the center in the first direction DR1, a first detour side area SDA1 parallel to the detour middle area MDDA in the first direction DR1 and in contact with the non-display area NDA, and a second detour side area SDA2 disposed between the detour middle area MDDA and the first detour side area SDA1.

The first detour side area SDA1 and the second detour side area SDA2 may be disposed between the detour middle area MDDA and the non-display area NDA on opposite sides of the detour middle area MDDA in the first direction DR1.

A part of the non-display area NDA in contact with the first detour side area SDA1 may include a shape bent along a point where two sides of the edge of the substrate 110 meet.

The general area GA may include a general middle area GMA connected to the detour middle area MDDA of the detour area DEA in the second direction DR2, a first general side area GSA1 connected to the first side area SDA1 of the detour area DEA in the second direction DR2, and a second general side area GSA2 connected to the second detour side area SDA2 of the detour area DEA in the second direction DR2.

In an embodiment of FIG. 4, the hole area HLA may be disposed in the general middle area GMA. However, this is only an illustrative embodiment, and the hole area HLA may be disposed anywhere in the display area DA. In an alternative embodiment, the hole area HLA may be disposed over the non-display area NDA and the display area DA.

The circuit layer 120 may further include, in the non-display area NDA, a scan driving circuit SCDA disposed adjacent to at least one side of the display area DA the first direction DR1. The scan driving circuit SCDA may supply respective gate signals to the gate lines disposed in the display area DA and extending in the first direction DR1.

In an embodiment, the display driving circuit 200 or the circuit board 300 may supply a scan control signal to the scan driving circuit SCDA based on digital video data and timing signals, for example.

The sub-region SBA may include a bending area BA that is transformed to be bent, and a first sub-region SB1 and the second sub-region SB2 that are respectively in contact with opposite sides of the bending area BA.

The first sub-region SB1 is disposed between the main region MA and the bending area BA. One side of the first sub-region SB1 may contact the non-display area NDA of the main region MA, and an opposite side of the first sub-region SB1 may contact the bending area BA.

The second sub-region SB2 is spaced apart from the main region MA with the bending area BA interposed therebetween, and faces the bottom surface of the substrate 110 by the bending area BA transformed to be bent. That is, the second sub-region SB2 may overlap the main region MA in a thickness direction DR3 of the substrate 110 due to the bending area BA transformed to be bent.

One side of the second sub-region SB2 may contact the bending area BA. An opposite side of the second sub-region SB2 may contact a part of the edge of the substrate 110.

The display driving circuit 200 may be disposed in the second sub-region SB2.

Further, the signal pads SPD bonded to the circuit board 300 may also be disposed in the second sub-region SB2.

FIG. 5 is a layout diagram illustrating part B of FIG. 4.

As described above with reference to FIG. 4, the detour area DEA on one side of the display area DA includes the detour middle area MDDA at the center, the first detour side area SDA1 parallel to the detour middle area MDDA in the first direction DR1 and in contact with the non-display area NDA, and the second detour side area SDA2 disposed between the detour middle area MDDA and the first detour side area SDA1.

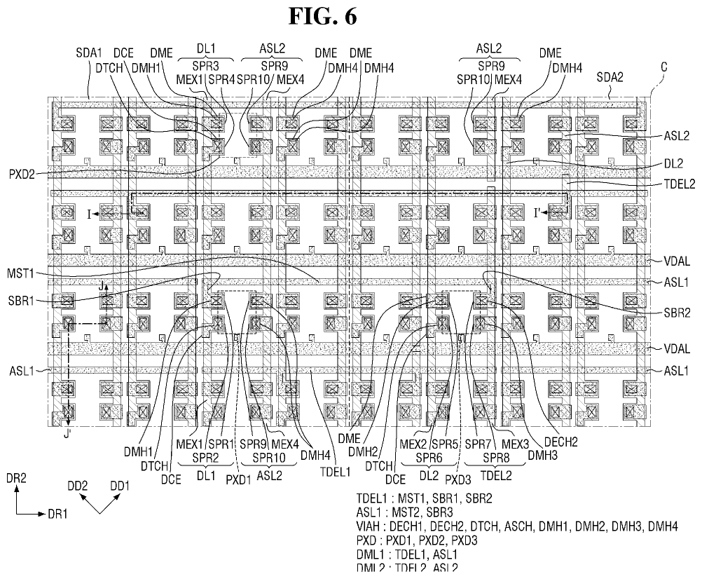

Referring to FIG. 5, the circuit layer 120 of the display panel 100 of the display device 10 in an embodiment includes the pixel drivers PXD (refer to FIG. 6) respectively corresponding to the emission areas EA, the data lines DL extending in the second direction DR2 and transmitting the data signals Vdata to the pixel drivers PXD, first dummy lines DML1 extending in the first direction DR1 crossing the data lines DL, and second dummy lines DML2 extending in the second direction DR2 in parallel with the data lines DL and adjacent to the data lines DL, respectively.

Although not illustrated in detail in FIG. 5, the circuit layer 120 may further include a first power supply line VDSPL and a second power supply line VSSPL extended from the second sub-region SB2, disposed in the non-display area NDA, and serving to transmit a first power ELVDD (refer to FIG. 11) and a second power ELVSS (refer to FIG. 11) for driving the light-emitting elements LEL of the light-emitting element layer 130, respectively, and first power auxiliary lines VDAL (refer to FIG. 6) disposed in the display area DA, extended in the first direction DR1, and electrically connected to the first power supply line VDSPL.

The first power supply line VDSPL and the second power supply line VSSPL may be electrically connected to the signal pads SPD disposed in the second sub-region SB2 of the sub-region SBA, and may extend to the non-display area NDA.

The first power supply line VDSPL and the second power supply line VSSPL may be disposed to surround at least a part of the display area DA.

The first dummy lines DML1 may be adjacent to the first power auxiliary lines VDAL, respectively.

The first dummy lines DML1 may include a first transmission detour line TDEL1 electrically connected to, among the data lines DL, a first data line DL1 disposed in the first detour side area SDA1, and first auxiliary lines ASL1 electrically connected to the second power supply line VSSPL.

Accordingly, in the detour area DEA, each of the first power auxiliary lines VDAL may include a portion adjacent to the first transmission detour line TDEL1 and another portion adjacent to the first auxiliary line ASL1.

In the general area GA, each of the first power auxiliary lines VDAL may be adjacent to the first auxiliary line ASL1.

The second dummy lines DML2 may include a second transmission detour line TDEL2 adjacent to, among the data lines DL, a second data line DL2 disposed in the second detour side area SDA2 and electrically connected to the first transmission detour line TDEL1, and second auxiliary lines ASL2 electrically connected to the second power supply line VSSPL.

The data lines DL may include the first data line DL1 disposed in the first side area SDA1 of the detour area DEA and the first general side area GSA1 of the general area GA, the second data line DL2 disposed in the second detour side area SDA2 of the detour area DEA and the second general side area GSA2 of the general area GA, and a third data line DL3 disposed in the detour middle area MDDA of the detour area DEA and the general middle area GMA of the general area GA.

Among the data lines DL, each of the data lines DL2 disposed in the second detour side area SDA2 of the detour area DEA and the second general side area GSA2 of the general area GA may include a portion adjacent to the second transmission detour line TDEL2 and another portion adjacent to the second auxiliary line ASL2.

Among the data lines DL, each of the first data lines DL1 disposed in the first side area SDA1 of the detour area DEA and the first general side area GSA1 of the general area GA, and each of the third data lines DL3 disposed in the detour middle area MDDA of the detour area DEA and the general middle area GMA of the general area GA may be adjacent to the second auxiliary line ASL2.

In other words, the circuit layer 120 of the display panel 100 of the display device 10 in an embodiment includes the pixel drivers PXD respectively corresponding to the emission areas EA, the data lines DL extending in the second direction DR2 and serving to transmit the data signals Vdata to the pixel drivers PXD, the first transmission detour line TDEL1 electrically connected to, among the data lines DL, the first data line DL1 disposed in the first detour side area SDA1 and extending in the first direction DR1, and the second transmission detour line TDEL2 adjacent to, among the data lines DL, the second data line DL2 disposed in the second detour side area SDA2, extending in the second direction DR2, and electrically connected to the first transmission detour line TDEL1.

The display device 10 in an embodiment may include the display driving circuit 200 disposed in the second sub-region SB2 of the sub-region SBA of the substrate 110 and serving to output the data signal Vdata of each of the data lines DL.

The circuit layer 120 may include the data supply lines DSPL disposed in the non-display area NDA and the sub-region SBA, electrically connected to the output terminals of the display driving circuit 200, respectively, and serving to transmit the data signal Vdata of each of the data lines DL to the display area DA.

The data supply lines DSPL may include a first data supply line DSPL1 for transmitting the data signal Vdata of the first data line DL1 of the first side area SDA1, a second data supply line DSPL2 for transmitting the data signal Vdata of the second data line DL2 of the second detour side area SDA2, and a third data line DLPL3 for transmitting the data signal Vdata of the third data line DL3 of the detour middle area MDDA.

The second data supply line DSPL2 may be connected to the second data line DL2.

The third data supply line DSPL3 may be connected to the third data line DL3.

The first data supply line DSPL1 for transmitting the data signal Vdata of the first data line DL1 may be connected to the second transmission detour line TDEL2 of the second detour side area SDA2.

Accordingly, the first data supply line DSPL1 does not extend to the first side area SDA1. Therefore, a portion of the non-display area NDA adjacent to the first side area SDA1 may have a reduced width because the first data supply line DSPL1 is not disposed therein.

A portion of the non-display area NDA adjacent to the first side area SDA1 includes a shape bent along the point where two sides of the edge of the substrate 110 meet. Accordingly, when the width of the portion of the non-display area NDA adjacent to the first side area SDA1 is reduced, the ratio of the display area DA in the main region MA may be increased, so that aesthetic impression of the display device 10 may be improved.

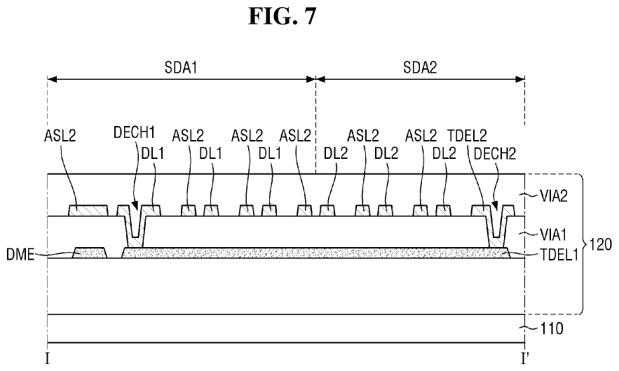

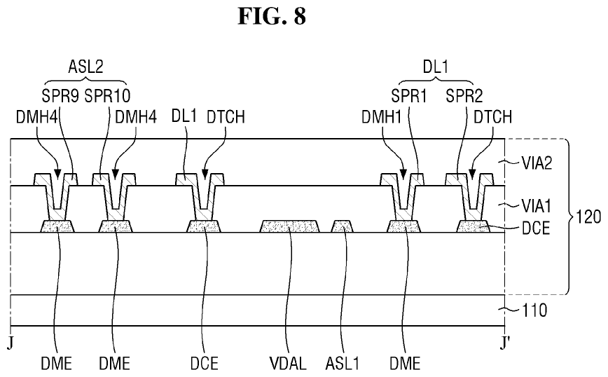

FIG. 6 is a layout diagram illustrating the data lines, the first dummy lines, the second dummy lines, and the first power auxiliary lines in part C of FIG. 4. FIG. 7 is a cross-sectional view showing a plane taken along line I-I′ of FIG. 6. FIG. 8 is a cross-sectional view showing a plane taken along line J-J′ of FIG. 6.

Referring to FIG. 6, the first transmission detour line TDEL1 of the display device 10 in an embodiment includes a first main stream MST1 extending in the first direction DR1 between the first data line DL1 and the second transmission detour line TDEL2, a first sub-branch SBR1 disposed in the first detour side area SDA1, extending in the second direction DR2 from the first main stream MST1, and overlapping a part of the first data line DL1, and a second sub-branch SBR2 disposed in the second detour side area SDA2, extending in the second direction DR2 from the first main stream MST1, and overlapping a part of the second transmission detour line TDEL2.

Each of the pixel drivers PXD of the circuit layer 120 may include a data connection electrode DCE electrically connected to one of the data lines DL through a data connection hole DTCH.

Referring to FIG. 7, the data lines DL and the second transmission detour line TDEL2 may be disposed on a via layer VIA1 covering the first transmission detour line TDEL1 and the data connection electrode DCE.

The data lines DL and the second transmission detour line TDEL2 may be covered with a planarization passivation layer VIA2.

In each of the pixel drivers PXD, the data connection hole DTCH may overlap the data connection electrode DCE and the data line DL and penetrate the via layer VIA1.

As shown in FIG. 6, the pixel drivers PXD may include a first pixel driver PXD1 adjacent to the first sub branch SBR1 of the first transmission detour line TDEL1.

The first data line DL1 may include a first main extension MEX1 extending in the second direction DR2, a first sub-protrusion SPR1 adjacent to the first pixel driver PXD1, protruding from the first main extension MEX1 and overlapping the first sub-branch SBR1, and a second sub-protrusion SPR2 adjacent to the first pixel driver PXD1, protruding from the first main extension MEX1 and overlapping the data connection hole DTCH of the first pixel driver PXD1.

The first transmission detour line TDEL1 may be electrically connected to the first data line DL1 through a first detour connection hole DECH1 overlapping the first sub-branch SBR1 of the first transmission detour line TDEL1 and the first sub-protrusion SPR1 of the first data line DL1.

As shown in FIG. 7, the first detour connection hole DECH1 for electrical connection between the first transmission detour line TDEL1 and the first data line DL1 may penetrate the via layer VIA1.

As described above, in an embodiment, the first detour connection hole DECH1 for electrical connection between the first transmission detour line TDEL1 and the first data line DL1 does not overlap the first main stream MST1 extending in the first direction DR1 in the first transmission detour line TDEL1, but overlaps the first sub-branch SBR1 extending in the second direction DR2 from the first main stream MST1. Accordingly, the first detour connection hole DECH1 may be spaced apart from an intersection between the first main stream MST1 of the first transmission detour line TDEL1 and the first main extension MEX1 of the first data line DL1. Therefore, the visibility of the end portion of the first main stream MST1 may be prevented from being increased due to the first detour connection hole DECH1.

As shown in FIG. 6, the first sub-branches SBR1 of the first transmission detour lines TDEL1 disposed in the first detour side area SDA1 may be arranged side by side in a predetermined second diagonal direction DD2 intersecting the first direction DR1 and the second direction DR2.

In this way, it may be easily inferred from the arrangement of the first sub branches SBR1 whether or not the electrical connection between the first data line DL1 and the first transmission detour line TDEL1 is normal.

In an embodiment, the pixel drivers PXD of the circuit layer 120 may further include a second pixel driver PXD2 disposed in the first detour side area SDA1, electrically connected to the first data line DL1, and spaced apart from the first pixel driver PXD1.

The first data line DL1 may further include a third sub-protrusion SPR3 and a fourth sub-protrusion SPR4 adjacent to the second pixel driver PXD2 and protruding from the first main extension MEX1.

The third sub-protrusion SPR3 may overlap a first dummy hole DMH1.

The first dummy hole DMH1 may overlap a dummy electrode DME covered with the via layer VIA1.

That is, since the first dummy hole DMH1 penetrates the via layer VIA1, the circuit layer 120 of the display device 10 in an embodiment may further include the dummy electrode DME overlapping the first dummy hole DMH1 to prevent other conductive layers under the via layer VIA1 from being damaged by the first dummy hole DMH1.

The fourth sub-protrusion SPR4 may overlap the data connection electrode DCE of the second pixel driver PXD2.

Among the first sub-protrusion SPR1, the second sub-protrusion SPR2, the third sub-protrusion SPR3 and the fourth sub-protrusion SPR4 of the first data line DL1, the third sub-protrusion SPR3 does not overlap the data connection hole DTCH and the first detour connection hole DECH1.

In an embodiment, the third sub-protrusion SPR3 of the first data line DL1 may overlap the first dummy hole DMH1.

As shown in FIG. 8, similarly to the first detour connection hole DECH1 and the data connection hole DTCH, the first dummy hole DMH1 may penetrate the via layer VIAL

The first dummy hole DMH1 may overlap the dummy electrode DME covered with the via layer VIAL That is, a part of the dummy electrode DME overlapping the first dummy hole DMH1 may be exposed by the first dummy hole DMH1. In other words, the dummy electrode DME may function as an etching prevention layer that protects components under the via layer VIA1 from the first dummy hole DMH1. Accordingly, a defect due to the first dummy hole DMH1 may be prevented.

Since the dummy electrode DME has an island-shaped pattern, the first dummy hole DMH1 and the dummy electrode DME may be irrelevant to the electrical connection.

As stated above, in an embodiment, since all of the first sub-protrusion SPR1, the second sub-protrusion SPR2, the third sub-protrusion SPR3 and the fourth sub-protrusion SPR4 of the first data line DL1 overlap via holes VIAH penetrating the via layer VIA1, visibility of the via holes VIAH may be lowered depending on the layout of the via holes VIAH.

Each of the second auxiliary lines ASL2 may include a fourth main extension MEX4 extending in the second direction DR2, and a ninth sub-protrusion SPR9 and a tenth sub-protrusion SPR10 protruding from the fourth main extension MEX4 to each of the pixel drivers PXD.

In an embodiment, the ninth sub-protrusion SPR9 of one second auxiliary line ASL2 adjacent to the first pixel driver PXD1 among the second auxiliary lines ASL2 may face the first sub-protrusion SPR1 of one first data line DL1 adjacent to the first pixel driver PXD1, for example. In addition, the tenth sub-protrusion SPR10 of one second auxiliary line ASL2 adjacent to the first pixel driver PXD1 may face the second sub-protrusion SPR2 of one first data line DL1 adjacent to the first pixel driver PXD1.

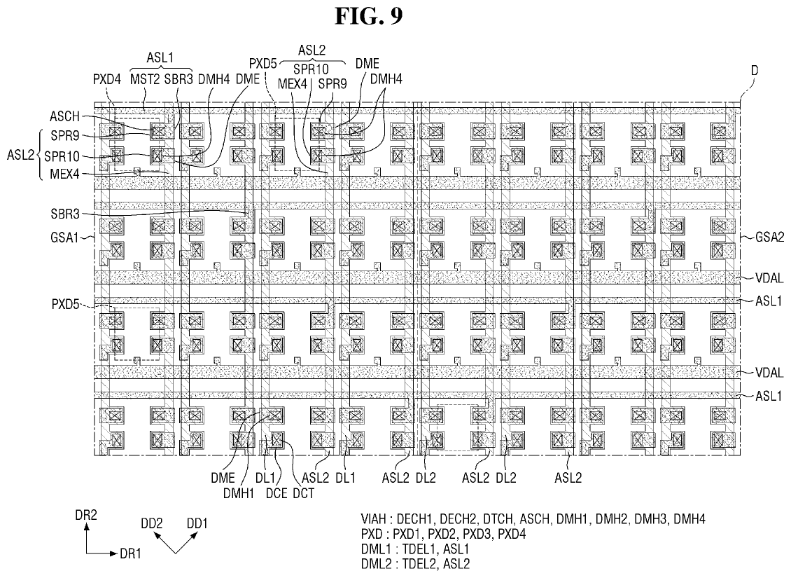

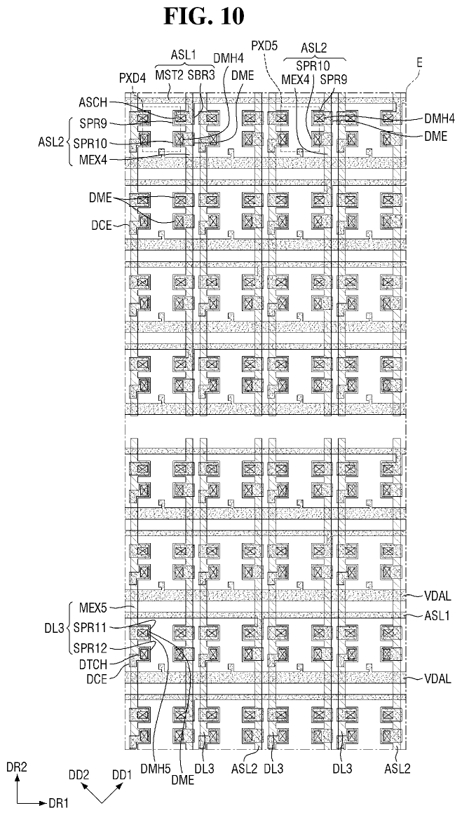

Besides, some of the ninth sub-protrusions SPR9 of the second auxiliary lines ASL2 may overlap an auxiliary connection hole ASCH (refer to FIGS. 9 and 10) penetrating the via layer VIA1 (refer to FIGS. 7 and 8).

Accordingly, the first auxiliary lines ASL1 may be electrically connected to the second auxiliary lines ASL2 through the auxiliary connection hole ASCH.

In addition, the others of the ninth sub-protrusions SPR9 of the second auxiliary lines ASL2 and the tenth sub-protrusions SPR10 of the second auxiliary lines ASL2 may overlap a fourth dummy hole DMH4.

As shown in FIG. 8, the fourth dummy hole DMH4 may penetrate the via layer VIA1 (refer to FIGS. 7 and 8).

Further, the fourth dummy hole DMH4 may overlap the dummy electrode DME covered with the via layer VIA1 (refer to FIGS. 7 and 8). That is, a part of the dummy electrode DME overlapping the fourth dummy hole DMH4 may be exposed by the fourth dummy hole DMH4.

Since the dummy electrode DME has an island-shaped pattern, the fourth dummy hole DMH4 may be irrelevant to the electrical connection.

In this way, both the ninth sub-protrusion SPR9 and the tenth sub-protrusion SPR10 of the second auxiliary line ASL2 may overlap the auxiliary connection hole ASCH or the fourth dummy hole DMH4. Since the auxiliary connection hole ASCH and the fourth dummy hole DMH4 are included in the via hole VIAH penetrating the via layer VIA1, visibility of the via hole VIAH may be lowered depending on the layout of the via hole VIAH.

In an embodiment, as shown in FIG. 6, the pixel drivers PXD of the circuit layer 120 may further include a third pixel driver PXD3 adjacent to the second sub branch SBR2 of the first transmission detour line TDEL1 and electrically connected to the second data line DL2.

The second data line DL2 disposed in the second detour side area SDA2 may include a second main extension MEX2 extending in the second direction DR2, a fifth sub-protrusion SPR5 adjacent to the third pixel driver PXD3, protruding from the second main extension MEX2, and disposed parallel to the first sub-protrusion SPR1 of the first data line DL1 in the first direction DR1, and a sixth sub-protrusion SPR6 adjacent to the third pixel driver PXD3, protruding from the second main extension MEX2, and disposed parallel to the second sub-protrusion SPR2 of the first data line DL1 in the first direction DR1.

Similarly to the second sub-protrusion SPR2 and the fourth sub-protrusion SPR4 of the first data line DL1, the sixth sub-protrusion SPR6 of the second data line DL2 may overlap the data connection electrode DCE of the third pixel driver PXD3.

Further, similarly to the third sub-protrusion SPR3 of the first data line DL1, the fifth sub-protrusion SPR5 of the second data line DL2 may overlap a second dummy hole DMH2.

Similarly to the first dummy hole DMH1, the second dummy hole DMH2 may penetrate the via layer VIA1 (refer to FIGS. 7 and 8). As the second dummy hole DMH2 overlaps the island-shaped dummy electrode DME covered with the via layer VIA1 (refer to FIGS. 7 and 8), it may be irrelevant to the electrical connection.

The second transmission detour line TDEL2 may include a third main extension MEX3 extending in the second direction DR2, a seventh sub-protrusion SPR7 adjacent to the third pixel driver PXD3, protruding from the third main extension MEX3, facing the fifth sub-protrusion SPR5 of the second data line DL2, and overlapping the second sub-branch SBR2 of the first transmission detour line TDEL1, and an eighth sub-protrusion SPR8 adjacent to the third pixel driver PXD3, protruding from the third main extension MEX3, and facing the sixth sub-protrusion SPR6 of the second data line DL2.

The second transmission detour line TDEL2 may be electrically connected to the second transmission detour line TDEL2 through a second detour connection hole DECH2 overlapping the second sub-branch SBR2 of the first transmission detour line TDEL1 and the seventh sub-protrusion SPR7 of the second transmission detour line TDEL2.

As shown in FIG. 7, similarly to the first detour connection hole DECH1, the second detour connection hole DECH2 for electrical connection between the first transmission detour line TDEL1 and the second transmission detour line TDEL2 may penetrate the via layer VIA1 (refer to FIGS. 7 and 8).

The eighth sub-protrusion SPR8 of the second transmission detour line TDEL2 may overlap a third dummy hole DMH3.

Similarly to the first dummy hole DMH1 and the second dummy hole DMH2, the third dummy hole DMH3 may penetrate the via layer VIAL (refer to FIGS. 7 and 8). In addition, as the third dummy hole DMH3 overlaps the island-shaped dummy electrode DME covered with the via layer VIA1 (refer to FIGS. 7 and 8), it may be irrelevant to the electrical connection.

As described above, in an embodiment, the second detour connection hole DECH2 for electrical connection between the first transmission detour line TDEL1 and the second transmission detour line TDEL2 does not overlap the first main stream MST1 extending in the first direction DR1 in the first transmission detour line TDEL1, but overlaps the second sub-branch SBR2 extending in the second direction DR2 from the first main stream MST1. Accordingly, the second detour connection hole DECH2 may be spaced apart from an intersection between the first main stream MST1 of the first transmission detour line TDEL1 and the third main extension MEX3 of the second transmission detour line TDEL2. Therefore, the visibility of the end portion of the first main stream MST1 may be prevented from being increased by the second detour connection hole DECH2.

Further, as shown in FIG. 6, the second sub-branches SBR2 of the first transmission detour lines TDEL1 disposed in the second detour side area SDA2 may be arranged side by side in a predetermined first diagonal direction DD1 intersecting the first direction DR1 and the second direction DR2.

In this way, it may be easily inferred from the arrangement of the second sub-branches SBR2 whether or not the electrical connection between the second transmission detour line TDEL2 and the first transmission detour line TDEL1 is normal.

FIG. 9 is a layout diagram illustrating data lines, first dummy lines, second dummy lines, and first power auxiliary lines in part D of FIG. 4.

Referring to FIG. 9, in the first general side area GSA1 in contact with the first detour side area SDA1 in the second direction DR2, the second auxiliary line ASL2 and the first data line DL1 of the first detour side area SDA1 may continuously extend in the second direction DR2.

In the second general side area GSA2 in contact with the second detour side area SDA2 in the second direction DR2, the second auxiliary line ASL2 and the second data line DL2 of the second detour side area SDA2 may continuously extend in the second direction DR2.

The first auxiliary lines ASL1 and the first power auxiliary lines VDAL extending in the first direction DR1 may be alternately disposed in the first general side area GSA1 and the second general side area GSA2.

FIG. 10 is a layout diagram illustrating data lines, first dummy lines, second dummy lines, and first power auxiliary lines in part E of FIG. 4.

Referring to FIG. 10, the data lines DL of the circuit layer 120 may further include the third data line DL3 disposed in the detour middle area MDDA and the general middle area GMA.

In an embodiment, as illustrated in FIGS. 6, 9, and 10, one of the first auxiliary lines ASL1 may include a second main stream MST2 extending in the first direction DR1, and a third sub-branch SBR3 extending from the second main stream MST2 in the second direction DR2 and overlapping a part of one of the second auxiliary lines ASL2.

The pixel drivers PXD of the circuit layer 120 may further include a fourth pixel driver PXD4 adjacent to the third sub-branch SBR3.

Among the second auxiliary lines ASL2, one second auxiliary line ASL2 overlapping the third sub-branch SBR3 may include a fifth main extension MEX5 extending in the second direction DR2, and an eleventh sub-protrusion SPR11 and a twelfth sub-protrusion SPR12 adjacent to the fourth pixel driver PXD4 and protruding from the fifth main extension MEX5.

One first auxiliary line ASL1 may be electrically connected to one second auxiliary line ASL2 through the auxiliary connection hole ASCH defined in the overlapping area between the third sub-branch SBR3 and the eleventh sub-protrusion SPR11.

As illustrated in FIG. 7, the auxiliary connection hole ASCH may penetrate the via layer VIAL

As described above, the auxiliary connection hole ASCH may not overlap the second main stream MST2 extending in the first direction DR1 in one first auxiliary line ASL1, and may be spaced apart from an intersection between the second main stream MST2 and the fifth main extension MEX5.

As illustrated in FIGS. 6 and 9, the third sub-branches SBR3 of the first auxiliary lines ASL1 adjacent to each other in the second direction DR2 may be arranged side by side in the first diagonal direction DD1 or the second diagonal direction.

Further, in the detour middle area MDDA and the general middle area GMA, the third sub-branches SBR3 of the first auxiliary lines ASL1 may be arranged side by side in one of the first diagonal direction DD1 and the second diagonal direction.

In an embodiment, as illustrated in FIG. 10, in the detour middle area MDDA and the general middle area GMA, the third sub branches SBR3 of the first auxiliary lines ASL1 may be arranged side by side in the first diagonal direction DD1, for example.

In this way, whether or not the electrical connection between the first auxiliary lines ASL1 and the second auxiliary lines ASL2 is normal may be easily inferred from the arrangement of the third sub-branches SBR3.

Each of the second auxiliary lines ASL2 may be electrically connected to two or more first auxiliary lines ASL1.

The twelfth sub-protrusion SPR12 of one second auxiliary line ASL2 may overlap a fifth dummy hole DMH5.

Similarly to the first dummy hole DMH1 and the second dummy hole DMH2, the fifth dummy hole DMH5 may penetrate the via layer VIA1 (refer to FIGS. 7 and 8). The fifth dummy hole DMH5 may overlap the island-shaped dummy electrode DME covered with the via layer VIA1 (refer to FIGS. 7 and 8), and thus may be irrelevant to the electrical connection.

In an embodiment, as shown in FIGS. 6, 9, and 10, the pixel drivers PXD of the circuit layer 120 may further include a fifth pixel driver spaced apart from the first sub-branch SBR1 and the second sub-branch SBR2 of the first transmission detour line TDEL1 and the third sub branch SBR3 of the first auxiliary line ASL1.

Among the second auxiliary lines ASL2, one second auxiliary line ASL2 adjacent to the fifth pixel driver may include a sixth main extension extending in the second direction DR2, and a fifteenth sub-protrusion and a sixteenth sub-protrusion adjacent to the fifth pixel driver and protruding from the sixth main extension.

Each of the fifteenth sub-protrusion and the sixteenth sub-protrusion may overlap a sixth dummy hole DMH6.

Similarly to the first dummy hole DMH1 and the second dummy hole DMH2, the sixth dummy hole DMH6 may penetrate the via layer VIA1 (refer to FIGS. 7 and 8). The sixth dummy hole DMH6 may overlap the island-shaped dummy electrode DME covered with the via layer VIA1 (refer to FIGS. 7 and 8), and thus may be irrelevant to the electrical connection.

As described above, in an embodiment, the first data line DL1 of the first detour side area SDA1 may be electrically connected to the second transmission detour line TDEL2 of the second detour side area SDA2 through the first transmission detour line TDEL1. The first transmission detour line TDEL1 includes the first main stream MST1 extending in the first direction DR1, the first sub-branch SBR1 extending from the first main stream MST1 in the second direction DR2 and overlapping the first sub-protrusion SPR1 of the first data line DL1, and the second sub-branch SBR2 extending from the first main stream MST1 in the second direction DR2 and overlapping the seventh sub-protrusion SPR7 of the second transmission detour line TDEL2.

The first detour connection hole DECH1 for electrical connection between the first data line DL1 and the first transmission detour line TDEL1 may overlap the first sub-protrusion SPR1 and the first sub-branch SBR1. Accordingly, the first detour connection hole DECH1 may be spaced apart from an intersection between the first main stream MST1 of the first transmission detour line TDEL1 and the first main extension MEX1 of the first data line DL1.

Further, the second detour connection hole DECH2 for electrical connection between the second transmission detour line TDEL2 and the first transmission detour line TDEL1 may overlap the seventh sub-protrusion SPR7 and the second sub-branch SBR2. Accordingly, the second detour connection hole DECH2 may be spaced apart from an intersection between the first main stream MST1 of the first transmission detour line TDEL1 and the third main extension MEX3 of the second transmission detour line TDEL2.

That is, opposite ends of the first main stream MST1 of the first transmission detour line TDEL1 may be spaced apart from the first detour connection hole DECH1 and the second detour connection hole DECH2.

Accordingly, it is possible to prevent the visibility of opposite ends of the first main stream MST1 of the first transmission detour line TDEL1 from being increased by the first detour connection hole DECH1 and the second detour connection hole DECH2.

Therefore, in an embodiment, the increase in the visibility of the first transmission detour line TEDL1, the second transmission detour line TDEL2, the first detour connection hole DECH1, and the second detour connection hole DECH2, which are provided for reducing the width of the non-display area NDA, may be prevented, so that the deterioration in the display quality of the display device 10 due to the first transmission detour line TDEL1 may be reduced.

Further, in an embodiment, the data lines DL and the second dummy lines DML2 extending in the second direction DR2 include a pair of sub-protrusions protruding toward each of the adjacent pixel drivers. Further, all the sub-protrusions included in the data lines DL and the second dummy lines DML2 overlap the via holes VIAH penetrating the via layer VIA1.

Here, the via hole VIAH collectively refers to holes penetrating the via layer VIAL That is, the via hole VIAH may include not only the first detour connection hole DECH1, the second detour connection hole DECH2, the data connection hole DTCH, and the auxiliary connection hole ASCH that are provided for electrical connection, but also the first dummy hole DMH1, the second dummy hole DMH2, the third dummy hole DMH3, and the fourth dummy hole DMH4 that are irrelevant to the electrical connection.

Among the via holes VIAH, the first dummy hole DMH1, the second dummy hole DMH2, the third dummy hole DMH3, and the fourth dummy hole DMH4, which are the holes except the first detour connection hole DECH1, the second detour connection hole DECH2, the data connection hole DTCH, and the auxiliary connection hole ASCH that overlap the data connection electrode DCE, the first sub-branch SBR1, the second sub branch SBR2, and the third sub-branch SBR3 may respectively overlap the dummy electrodes DME covered with the via layer VIA1.

Due to the dummy electrodes DME, the first planarization layer 125 may be protected from the first dummy hole DMH1, the second dummy hole DMH2, the third dummy hole DMH3, and the fourth dummy hole DMH4.

As described above, in an embodiment, the via holes VIAH penetrating the via layer VIA1 further include the first to fourth dummy holes DMH1 to DMH4 that are irrelevant to the electrical connection, so that the visibility of the first detour connection hole DECH1, the second detour connection hole DECH2, the data connection hole DTCH, and the auxiliary connection hole ASCH that are provided for electrical connection may be decreased.

Therefore, the deterioration in the display quality of the display device 10 due to the visibility of the via holes VIAH may be reduced.

FIG. 11 is an equivalent circuit diagram showing one embodiment of one pixel driver of the circuit layer of FIG. 3.

Referring to FIG. 11, one of the pixel drivers PXD of the circuit layer 120 may include a driving transistor DT, at least one of switch elements ST1 to ST6, and a capacitor C1. At least one of the switch elements ST1 to ST6 may include a first transistor (switch transistor) ST1, a second transistor ST2, a third transistor ST3, a fourth transistor ST4, a fifth transistor ST5, and a sixth transistor ST6.

The circuit layer 120 may further include a scan write line GWL that transmits a scan write signal GW to the pixel drivers PXD, a gate control line GCL that transmits a gate control signal GC to the pixel drivers PXD, a scan initialization line GIL that transmits a scan initialization signal GI to the pixel drivers PXD, an emission control line ECL that transmits an emission control signal EC to the pixel drivers PXD, a gate initialization voltage line VGIL that transmits a first initialization voltage Vgint to the pixel drivers PXD, an anode initialization voltage line VAIL that transmits a second initialization voltage Vaint to the pixel drivers PXD, and a first power line VDL that transmits the first power ELVDD to the pixel drivers PXD.

The scan write line GWL may be electrically connected to the gate electrode of each of the first transistor ST1 and the second transistor ST2. The scan initialization line GIL may be electrically connected to the gate electrode of the third transistor ST3. The gate control line GCL may be electrically connected to the gate electrode of the fourth transistor ST4. The emission control line ECL may be electrically connected to the gate electrode of each of the fifth transistor ST5 and the sixth transistor ST6.

The driving transistor DT may be connected in series with the light-emitting element LEL between the first power line VDL and a second power line VSL.

The first electrode of the driving transistor DT may be connected to the first power line VDL through the fifth transistor ST5.

Also, the first electrode of the driving transistor DT may be connected to the data line DL through the second transistor ST2.

The second electrode of the driving transistor DT may be connected to the light-emitting element LEL through the sixth transistor ST6.

The capacitor C1 may be connected between the first power line VDL and the gate electrode of the driving transistor DT. That is, the gate electrode of the driving transistor DT may be connected to the first power line VDL through the capacitor C1.

Accordingly, when the data signal of the data line DL is applied to the first electrode of the driving transistor DT, the driving transistor DT may generate a drain-source current corresponding to the data signal. The drain-source current of the driving transistor DT may be supplied as the driving current of the light-emitting element LEL.

The light-emitting element LEL may emit light having a luminance corresponding to the driving current of the driving transistor DT.

The light-emitting element LEL may include an anode electrode AND (refer to FIG. 15) and a cathode electrode CTD (refer to FIG. 15) disposed to face each other, and a light-emitting layer EML (refer to FIG. 15) between the anode electrode AND and the cathode electrode CTD.

In an embodiment, the light-emitting element LEL may be an organic light-emitting diode having a light-emitting layer including an organic light-emitting material. In an alternative embodiment, the light-emitting element LEL may be an inorganic light-emitting element including a light-emitting layer including an inorganic semiconductor. In an alternative embodiment, the light-emitting element LEL may be a quantum dot light-emitting element having a quantum dot light-emitting layer. In an alternative embodiment, the light-emitting element LEL may be a micro light-emitting diode.

A capacitor Ce1 connected in parallel with the light-emitting element LEL is a parasitic capacitance between the anode electrode and the cathode electrode.

The first transistor ST1 is connected between the gate electrode of the driving transistor DT and the second electrode of the driving transistor DT.

The first transistor ST1 may include a plurality of sub-transistors connected in series. In an embodiment, the first transistor ST1 may include a first sub-transistor ST11 and a second sub-transistor ST12, for example.

The first electrode of the first sub-transistor ST11 may be connected to the second electrode of the driving transistor DT, the second electrode of the first sub-transistor ST11 may be connected to the first electrode of the second sub-transistor ST12, and the second electrode of the second sub-transistor ST12 may be connected to the gate electrode of the driving transistor DT.

In this way, it is possible to prevent the potential of the gate electrode of the driving transistor DT from changing due to the leakage current caused by the first transistor ST1 that is turned off.

The second transistor ST2 is connected between the first electrode of the driving transistor DT and the data line DL.

The gate electrode of each of the first transistor ST1 and the gate electrode of the second transistor ST2 is connected to the scan write line GWL.

When the scan write signal GW is transmitted through the scan write line GWL, the first transistor ST1 and the second transistor ST2 are turned on, and the gate electrode and the second electrode of the driving transistor DT become to have the same potential through the turned-on first transistor ST1. Further, the data signal of the data line DL is supplied to the first electrode of the driving transistor DT through the turned-on second transistor ST2.

At this time, when the voltage difference between the first electrode and the gate electrode of the driving transistor DT becomes larger than a threshold voltage, the driving transistor DT is turned on to generate a drain-source current between the first electrode and the second electrode of the driving transistor DT.

The third transistor ST3 is connected between the gate electrode of the driving transistor DT and the gate initialization voltage line VGIL. The gate electrode of the third transistor ST3 is connected to the scan initialization line GIL.

The third transistor ST3 may include a plurality of sub-transistors connected in series. In an embodiment, the third transistor ST3 may include a third sub-transistor ST31 and a fourth sub-transistor ST32, for example.

The first electrode of the third sub-transistor ST31 may be connected to the gate electrode of the driving transistor DT, the second electrode of the third sub-transistor ST31 may be connected to the first electrode of the fourth sub-transistor ST32, and the second electrode of the fourth sub-transistor ST32 may be connected to the gate initialization voltage line VGIL.

In this way, it is possible to prevent the potential of the gate electrode of the driving transistor DT from changing due to the leakage current caused by the third transistor ST3 that is turned off.

When the scan initialization signal GI is supplied through the scan initialization line GIL, the third transistor ST3 may be turned on. At this time, the gate electrode of the driving transistor DT is connected to the gate initialization voltage line VGIL through the turned-on third transistor ST3, so that the potential of the gate electrode of the driving transistor DT may be initialized to the first initialization voltage Vgint of the gate initialization voltage line VGIL.

The fourth transistor ST4 may be connected between the anode electrode of the light-emitting element LEL and the anode initialization voltage line VAIL. The gate electrode of the fourth transistor ST4 may be connected to the gate control line GCL.

When the control scan signal GC is supplied through the gate control line GCL, the fourth transistor ST4 may be turned on. At this time, the anode electrode of the light-emitting element LEL is connected to the anode initialization voltage line VAIL through the turned-on fourth transistor ST4, so that the potential of the anode electrode of the light-emitting element LEL may be initialized to the second initialization voltage Vaint of the anode initialization voltage line VAIL.

The fifth transistor ST5 may be connected between the first electrode of the driving transistor DT and the first power line VDL.

The sixth transistor ST6 may be connected between the second electrode of the driving transistor DT and the anode electrode of the light-emitting element LEL.

The gate electrode of each of the fifth transistor ST5 and the sixth transistor ST6 may be connected to the emission control line ECL.

When the emission control signal EC is supplied through the emission control line ECL, the driving transistor DT and the light-emitting element LEL may be connected in series between the first power line VDL and the second power line VSL. Accordingly, the driving current of the driving transistor DT may be supplied to the light-emitting element LEL and, thus, the light-emitting element LEL may emit light based on the driving current.

As shown in FIG. 11, the driving transistor DT and one or more switch elements ST1 to ST6 provided in the pixel driver PXD may be all implemented as P-type MOSFETs.

In an alternative embodiment, some of the one or more switch elements ST1 to ST6 and the driving transistor DT provided in the pixel driver PXD may be implemented as P-type MOSFETs, while the others may be implemented as N-type MOSFETs. In this case, the switch elements implemented as P-type MOSFETs and the switch elements implemented as N-type MOSFETs may include active layers of different semiconductor materials. Therefore, the width of the pixel driver PXD may be reduced through the stacked structure, which may be advantageous to improve resolution.

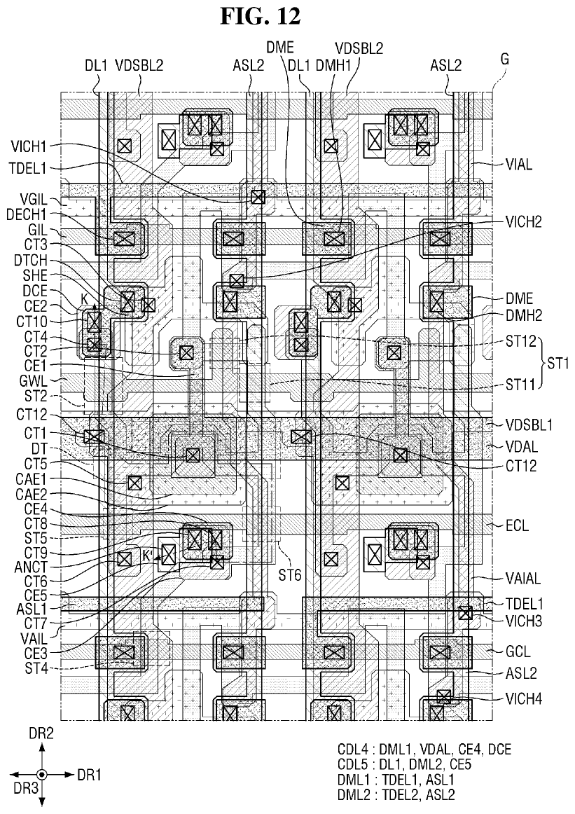

FIG. 12 is a plan view showing part G of FIG. 5 according to a first embodiment. FIG. 13 is a plan view illustrating a semiconductor layer, a first conductive layer, a second conductive layer, and a third conductive layer in the plan view of FIG. 12. FIG. 14 is a plan view showing a fourth conductive layer and a fifth conductive layer in the plan view of FIG. 12. FIG. 15 is a cross-sectional view taken along line K-K′ of FIG. 12.

FIG. 12 is a plan view showing two pixel drivers PXD disposed in the first detour side area SDA1 and adjacent to each other in the first direction DR1.

First, as shown in FIG. 15, in an embodiment, the circuit layer 120 may have a structure including a semiconductor layer SEL (refer to FIG. 13) on the substrate 110, a first conductive layer CDL1 (refer to FIG. 13) on a first gate insulating layer 122 covering the semiconductor layer SEL, a second conductive layer CDL2 (refer to FIG. 13) on a second gate insulating layer 123 covering the first conductive layer CDL1, a third conductive layer CDL3 (refer to FIG. 13) on an inter-insulating layer 124 covering the second conductive layer CDL2, a fourth conductive layer CDL4 (refer to FIG. 12) on a first planarization layer 125 covering the third conductive layer CDL3, a fifth conductive layer CDL5 (refer to FIG. 12) on a second planarization layer 126 covering the fourth conductive layer CDL4, and a third planarization layer 127 covering the fifth conductive layer CDL5.

Further, the light-emitting element layer 130 may be disposed on the third planarization layer 127.

Referring to FIG. 13, the semiconductor layer SEL may include channel portions CHDT, CH11, CH12, CH2, CH31, CH32, CH4, CH5, and CH6, source electrodes SDT, S11, S12, S2, S31, S32, S4, S5, and S6 and drain electrodes DDT, D11, D12, D2, D31, D32, D4, D5, and D6 of the driving transistor DT and the first to sixth transistors ST1 to ST6.

In the semiconductor layer SEL, the source electrodes SDT, S11, S12, S2, S31, S32, S4, S5, and S6 and the drain electrodes DDT, D11, D12, D2, D31, D32, D4, D5, and D6 may include or consist of portions having conductivity by doping a semiconductor material with ions or impurities.

The first conductive layer CDL1 may include gate electrodes GDT, G11, G12, G2, G31, G32, G4, G5, and G6 of the driving transistor DT and the first to sixth transistors ST1 to ST6.

In addition, the first conductive layer CDL1 may further include the scan write line GWL, the scan initialization line GIL, the emission control line ECL, and the gate control line GCL connected to the gate electrodes GDT, G11, G12, G2, G31, G32, G4, G5, and G6 of the first to sixth transistors ST1 to ST6. The scan write line GWL, the scan initialization line GIL, the emission control line ECL, and the gate control line GCL may extend in the first direction DR1.

In an embodiment, for integration of the circuit layer 120, the gate control line GCL of a current column may be provided as the scan initialization line GIL of a previous column, for example.

The second conductive layer CDL2 may include the gate initialization voltage line VGIL that transmits the first initialization voltage Vgint and the anode initialization voltage line VAIL that transmits the second initialization voltage Vaint. The gate initialization voltage line VGIL and the anode initialization voltage line VAIL may extend in the first direction DR1.

The first power line VDL may include a first power horizontal auxiliary line VDSBL1 extending in the first direction DR1 and a first power vertical auxiliary line VDSBL2 extending in the second direction DR2.

The second conductive layer CDL2 may further include the first power horizontal auxiliary line VDSBL1.

The third conductive layer CDL3 may include the first power vertical auxiliary line VDSBL2.

The third conductive layer CDL3 may further include a gate initialization voltage auxiliary line VGIAL and an anode initialization voltage auxiliary line VAIAL.

The gate initialization voltage auxiliary line VGIAL and the anode initialization voltage auxiliary line VAIAL may be electrically connected to the initialization voltage line VAIL and may extend in the second direction DR2.

The gate initialization voltage auxiliary line VGIAL may be electrically connected to the gate initialization voltage line VGIL through a first initialization connection hole VICH1, and may be electrically connected to the drain electrode D32 of the third transistor ST3 through a second initialization connection hole VICH2.

The anode initialization voltage auxiliary line VAIAL may be electrically connected to the anode initialization voltage line VAIL through a third initialization connection hole VICH3, and may be electrically connected to the drain electrode D4 of the fourth transistor ST4 through a fourth initialization connection hole VICH4.

The first power vertical auxiliary line VDSBL2 may be electrically connected to the first power horizontal auxiliary line VDSBL1 through the fifth contact hole CT5.

The driving transistor DT may include the channel portion CHDT, the source electrode SDT and the drain electrode DDT connected to opposite sides of the channel portion CHDT, and the gate electrode GDT overlapping the channel portion CHDT.

The source electrode SDT of the driving transistor DT may be connected to the drain electrode D2 of the second transistor ST2 and the drain electrode D5 of the fifth transistor ST5.

The drain electrode DDT of the driving transistor DT may be connected to a source electrode S11 of an eleventh transistor ST11 and a source electrode S6 of the sixth transistor ST6.

The gate electrode GDT of the driving transistor DT may be provided as the first conductive layer CDL1.

The first transistor ST1 may include the first sub-transistor ST11 and the second sub-transistor ST12 connected in series.

The first sub-transistor ST11 may include the channel portion CH11, the source electrode S11 and the drain electrode D11 connected to opposite sides of the channel portion CH11, and the gate electrode G11 that overlaps the channel portion CH11 and includes or consists of a part of the scan write line GWL.

The source electrode S11 of the first sub-transistor ST11 may be connected to the drain electrode DDT of the driving transistor DT.

The drain electrode D11 of the first sub-transistor ST11 may be connected to the source electrode S12 of the second sub-transistor ST12.

The second sub-transistor ST12 may include the channel portion CH12, the source electrode S12 and the drain electrode D12 connected to opposite sides of the channel portion CH12, and the gate electrode G12 that overlaps the channel portion CH12 and includes or consists of a protruding portion of the scan write line GWL.

The source electrode S12 of the second sub-transistor ST12 may be connected to the drain electrode D11 of the first sub-transistor ST11.

The drain electrode D12 of the second sub-transistor ST12 may be connected to the source electrode S31 of the third sub-transistor ST31.

The gate electrode G11 of the first sub-transistor ST11 and the second electrode G12 of the second sub-transistor ST12 may include or consist of different parts of the scan write line GWL.

The gate electrode GDT of the driving transistor DT may be electrically connected to the first connection electrode CE1 through the first contact hole CT1, and the first connection electrode CE1 may be electrically connected to the drain electrode D12 of the second sub-transistor ST12 through the second contact hole CT2.

The first connection electrode CE1 may include or consist of the third conductive layer CDL3.

The second transistor ST2 may include the channel portion CH2, the source electrode S2 and drain electrode D2 connected to opposite sides of the channel portion CH2, and the gate electrode G2 that overlaps the channel portion CH2 and includes or consists of a part of the scan write line GWL.

The source electrode S2 of the second transistor ST2 may be electrically connected to the second connection electrode CE2 through a fourth contact hole CT4.

The second connection electrode CE2 may be provided as the third conductive layer CDL3.

The drain electrode D2 of the second transistor ST2 may be connected to the source electrode SDT of the driving transistor DT and the drain electrode D5 of the fifth transistor ST5.

The third transistor ST3 may include the third sub-transistor ST31 and the fourth sub-transistor ST32 connected in series.

The third sub-transistor ST3 may include the channel portion CH31, the source electrode S31 and the drain electrode D31 connected to opposite sides of the channel portion CH31, and the gate electrode G31 overlapping the channel portion CH31.

The source electrode S31 of the third sub-transistor ST31 may be connected to the drain electrode D12 of the second sub-transistor ST12.

The drain electrode D31 of the third sub-transistor ST31 may be connected to the source electrode S32 of the fourth sub-transistor ST32.

The fourth sub-transistor ST32 includes the channel portion CH32, the source electrode S32 and the drain electrode D32 connected to opposite sides of the channel portion CH32, and the gate electrode G32 overlapping the channel portion CH32.

The drain electrode D32 of the fourth sub-transistor ST32 may be electrically connected to an initialization auxiliary line VIAL through the second initialization contact hole VICH2.

The gate electrode G31 of the third sub-transistor ST31 and the gate electrode G32 of the fourth sub-transistor ST32 may include or consist of different parts of the scan initialization line GIL.

The pixel driver PXD may further include a shielding electrode SHE overlapping at least a part of the source electrode S31 of the third sub-transistor ST31. The shielding electrode SHE may further overlap a part of the drain electrode D11 of the first sub-transistor ST11.

The shielding electrode SHE may be provided as the second conductive layer CDL2.

The shielding electrode SHE may be electrically connected to the first power vertical auxiliary line VDSBL2 through a third contact hole CT3.

The fourth transistor ST4 may include a channel portion CH4, a source electrode S4 and a drain electrode D4 connected to opposite sides of the channel portion CH4, and a gate electrode G4 overlapping the channel portion CH4 and including or consisting of a portion of the gate control line GCL.

The source electrode S4 of the fourth transistor ST4 may be connected to the drain electrode D6 of the sixth transistor ST6.

The drain electrode D4 of the fourth transistor ST4 may be electrically connected to the initialization auxiliary line VIAL through the third initialization connection hole VICH3.

The fifth transistor ST5 may include the channel portion CH5, the source electrode S5 and the drain electrode D5 connected to opposite sides of the channel portion CH5, and the gate electrode G5 that overlaps the channel portion CH5 and includes or consists of a part of the emission control line ECL.

The source electrode S5 of the fifth transistor ST5 may be electrically connected to the first power vertical auxiliary line VDSBL2 through a sixth contact hole CT6.

The drain electrode D5 of the fifth transistor ST5 may be connected to the source electrode SDT of the driving transistor DT.

The sixth transistor ST6 may include the channel portion CH6, the source electrode S6 and drain electrode D6 connected to opposite sides of the channel portion CH6, and the gate electrode G6 that overlaps the channel portion CH6 and includes or consists of another part of the emission control line ECL.

The source electrode S6 of the sixth transistor ST6 may be connected to the drain electrode DDT of the driving transistor DT.

The drain electrode D6 of the sixth transistor ST6 may be connected to the source electrode S4 of the fourth transistor ST4 and may be connected to a third connection electrode CE3 through a seventh contact hole CT7.

The third connection electrode CE3 may include or consist of the third conductive layer CDL3.

The capacitor C1 may be provided as an overlapping area between a first capacitor electrode CAE1 and a second capacitor electrode CAE2.

The first capacitor electrode CAE1 may include or consist of a part of the gate electrode GDT of the driving transistor DT, which is provided as the first conductive layer CDL1.

The second capacitor electrode CAE2 may include or consist of a part of the first power horizontal auxiliary line VDSBL1, which is provided as the second conductive layer CDL2.

The second connection electrode CE2 may be electrically connected to the source electrode S2 of the second transistor ST2 through the fourth contact hole CT4.

Referring to FIG. 14, the fourth conductive layer CDL4 may include the first transmission detour line TDEL1 and the first power auxiliary line VDAL. Since the first transmission detour line TDEL1 is included in the first dummy line DML1, the fourth conductive layer CDL4 may include the first dummy line DML1 and the first power auxiliary lines VDAL. Further, the first dummy line DML1 may include the first transmission detour line TDEL1 and the first auxiliary line ASL1.

The first power auxiliary line VDAL may be electrically connected to the first power vertical auxiliary line VDSBL2 of the third conductive layer CDL3 through a twelfth contact hole CT12.

The fourth conductive layer CDL4 may further include a fourth connection electrode CE4, the data connection electrode DCE, and the dummy electrode DME.

The data connection electrode DCE may be electrically connected to the second connection electrode CE2 through a tenth contact hole CT10. The second connection electrode CE2 may be electrically connected to the source electrode S2 of the second transistor ST2 through the fourth contact hole CT4.

The fifth conductive layer CDL5 may include the data lines DL including the first data line DL1, and the second dummy lines DML2 respectively adjacent to the data lines DL. The second dummy lines DML2 may include the second transmission detour line TDEL2 and the second auxiliary line ASL2.

The fifth conductive layer CDL5 may further include a fifth connection electrode CE5.

The first data line DL1 may be electrically connected to the data connection electrode DCE through the data connection hole DTCH.

Accordingly, the first data line DL1 may be electrically connected to the source electrode S2 of the second transistor ST2 through the second connection electrode CE2, the data connection electrode DCE, and the data connection hole DTCH.

The fourth connection electrode CE4 may be electrically connected to the third connection electrode CE3 through an eighth contact hole CTB. The third connection electrode CE3 may be electrically connected to the source electrode S4 of the fourth transistor ST4 and the drain electrode D6 of the sixth transistor ST6, which are provided as the semiconductor layer SEL, through the seventh contact hole CT7.

The fifth connection electrode CE5 may be electrically connected to the fourth connection electrode CE4 through a ninth contact hole CT9.

Further, as shown in FIGS. 14 and 15, the fifth connection electrode CE5 may be electrically connected to the anode electrode AND of the light-emitting element LEL through an anode contact hole ANCT penetrating the third planarization layer 127.

Accordingly, the anode electrode AND of the light-emitting element LEL may be electrically connected to the fourth transistor ST4 and the sixth transistor ST6 through the third connection electrode CE3, the fourth connection electrode CE4, the fifth connection electrode CE5, and the anode contact hole ANCT.

In accordance with the first embodiment, among the first dummy lines DML1, the first transmission detour line TDEL1 includes the first main stream MST1 extending in the first direction DR1, and the first sub-branch SBR1 extending from the first main stream MST1 in the second direction DR2 and overlapping the first sub-protrusion SPR1 of the first data line DL1.

The first main stream MST1 of the first transmission detour line TDEL1 may be spaced apart from the scan initialization line GIL with the gate initialization voltage line VGIL interposed therebetween in the second direction DR2 or the third direction DR3.

In an embodiment, in the second direction DR2, the gate initialization voltage line VGIL may be disposed between the first main stream MST1 of the first transmission detour line TDEL1 and the scan initialization line GIL, for example.

In an alternative embodiment, the gate initialization voltage line VGIL may overlap the first main stream MST1 of the first transmission detour line TDEL1 in the third direction DR3, and may be spaced apart from the scan initialization line GIL in the second direction DR2.

In this way, a defect in which the scan initialization signal GI of the scan initialization line GIL is coupled with the data signal Vdata of the first data line DL1 transmitted through the first transmission detour line TDEL1 may be prevented.

The first data line DL1 may include the first main extension MEX1 extending in the second direction DR2, and the first sub-protrusion SPR1 and the second sub-protrusion SPR2 protruding from the first main extension MEX1.

The first sub-protrusion SPR1 may overlap the first sub-branch SBR1, and the second sub-protrusion SPR2 may overlap the data connection hole DTCH for electrical connection between the source electrode S2 of the second transistor ST2 and the first data line DL1.

The first detour connection hole DECH1 for electrical connection between the first transmission detour line TDEL1 and the first data line DL1 may overlap the first sub-branch SBR1 and the first sub-protrusion SPR1.

Here, the first main stream MST1 of the first transmission detour line TDEL1 may be spaced apart from each of the first sub-protrusion SPR1 and the second sub-protrusion SPR2 of the first data line DLL Further, the first main stream MST1 of the first transmission detour line TDEL1 may be disposed closer to the first sub-protrusion SPR1, between the first sub-protrusion SPR1 and the second sub-protrusion SPR2 of the first data line DL1, in the second direction DR2. In this way, the first sub-branch SBR1 may have a relatively small length, and may be spaced apart from the data connection electrode DCE for electrical connection between the first data line DL1 and the second transistor ST2.

As shown in FIG. 6, the first data line DL1 may further include the third sub-protrusion SPR3 and the fourth sub-protrusion SPR4 that are spaced apart from the first sub-branch SBR1 of the first transmission detour line TDEL1, are adjacent to the general area GA, and protrude from the first main extension MEX1.

The third sub-protrusion SPR3 may overlap the first dummy hole DMH1 that is irrelevant to the electrical connection.

The fourth sub-protrusion SPR4 may overlap the data connection hole DTCH.

The second auxiliary line ASL2 may include the fourth main extension MEX4 extending in the second direction DR2, and the ninth sub-protrusion SPR9 and the tenth sub-protrusion SPR10 protruding from the fourth main extension MEX4 toward each of the pixel drivers PXD.

Some of the ninth sub-protrusions SPR9 of the second auxiliary lines ASL2 may overlap the auxiliary connection hole ASCH for electrical connection between the first auxiliary line ASL1 and the second auxiliary line ASL2.

That is, among the first dummy lines DML1, one first auxiliary line ASL1 may include the second main stream MST2 extending in the first direction DR1, and the third sub-branch SBR3 extending from the second main stream MST2 in the second direction DR2 and overlapping one second auxiliary line ASL2.

Some of the ninth sub-protrusions SPR9 of the second auxiliary lines ASL2 may overlap the auxiliary connection hole ASCH penetrating the via layer VIA1, and the third sub-branch SBR3 of the first auxiliary line ASL1. Accordingly, the first auxiliary lines ASL1 may be electrically connected to the second auxiliary lines ASL2 through the auxiliary connection hole ASCH overlapping the third sub-branch SBR3 of the first auxiliary line ASL1 and the ninth sub-protrusion SPR9 of the second auxiliary line ASL2.

Further, the others of the ninth sub-protrusions SPR9 of the second auxiliary lines ASL2, and the tenth sub-protrusions SPR10 of the second auxiliary lines ASL2 may overlap the fourth dummy hole DMH4 and the dummy electrode DME.

In an embodiment, the ninth sub-protrusion SPR9 and the tenth sub-protrusion SPR10 of one second auxiliary line ASL2 that is adjacent to the first data line DL1 among the second auxiliary lines ASL2 may face the first sub-protrusion SPR1 and the second sub-protrusion SPR2 of the first data line DL1, respectively, for example. Further, each of the ninth sub-protrusion SPR9 and the tenth sub-protrusion SPR10 of one second auxiliary line ASL2 adjacent to the first data line DL1 may overlap the fourth dummy hole DMH4 and the dummy electrode DME.

Referring to FIG. 15, the circuit layer 120 may include the semiconductor layer SEL on the substrate 110, the first conductive layer CDL1 on the first gate insulating layer 122 covering the semiconductor layer SEL, the second conductive layer CDL2 on the second gate insulating layer 123 covering the first conductive layer CDL1, the third conductive layer CDL3 on the inter-insulating layer 124 covering the second conductive layer CDL2, the fourth conductive layer CDL4 on the first planarization layer 125 covering the third conductive layer CDL3, the fifth conductive layer CDL5 on the second planarization layer 126 covering the fourth conductive layer CDL4, and the third planarization layer 127 covering the fifth conductive layer CDL5.

The circuit layer 120 may further include a buffer layer 121 disposed between the substrate 110 and the semiconductor layer SEL.

The buffer layer 121 may be used to protect the circuit layer 120 and the light-emitting element layer 130 from moisture penetrating through the substrate 110, and may include or consist of at least one inorganic layer.

In an embodiment, the buffer layer 121 may be formed as multiple layers in which one or more inorganic layers of silicon nitride, silicon oxynitride, silicon oxide, titanium oxide, and aluminum oxide are alternately stacked, for example.

The semiconductor layer SEL is disposed on the buffer layer 121, and may include or consist of a silicon semiconductor such as polycrystalline silicon, single crystal silicon, low-temperature polycrystalline silicon, and amorphous silicon.

The semiconductor layer SEL may include the channel portions CHDT, CH11, CH12, CH2, CH31, CH32, CH4, CH5, and CH6 of FIG. 13 of the driving transistor DT and the first to sixth transistors ST1 to ST6 provided in the pixel driver PXD.

In addition, the semiconductor layer SEL may further include the source electrodes SDT, S11, S12, S2, S31, S32, S4, S5, and S6 of FIG. 13 and the drain electrodes DDT, D11, D12, D2, D31, D32, D4, D5, and D6 of FIG. 13 of the driving transistor DT and each of the switch elements ST1 to ST6.

Another portion corresponding to the source electrodes SDT, S11, S12, S2, S31, S32, S4, S5, and S6 of FIG. 13 and the drain electrodes DDT, D11, D12, D2, D31, D32, D4, D5, and D6 of FIG. 13 of the driving transistor DT and each of the switch elements ST1 to ST6 of the semiconductor layer SEL may be doped with ions or impurities to have conductivity.

A portion corresponding to the channel portions CHDT, CH11, CH12, CH2, CH31, CH32, CH4, CH5, and CH6 of FIG. 13 of the driving transistor DT and each of the switch elements ST1 to ST6 of the semiconductor layer SEL may not be doped by the gate electrodes GDT, G11, G12, G2, G31, G32, G4, G5, and G6, and may maintain the characteristics of a semiconductor that generates a channel serving as a carrier movement path depending on the potential difference.

The first gate insulating layer 122 may include or consist of an inorganic layer disposed on the buffer layer 121 and covering the semiconductor layer SEL.

In an embodiment, the first gate insulating layer 122 may include or consist of an inorganic layer of a silicon nitride layer, a silicon oxynitride layer, a silicon oxide layer, a titanium oxide layer, or an aluminum oxide layer, for example.

The first conductive layer CDL1 is disposed on the first gate insulating layer 122.

As shown in FIG. 13, the first conductive layer CDL1 may include the gate electrodes GDT, G11, G12, G2, G31, G32, G4, G5, and G6 of the driving transistor DT and the switch elements ST1 to ST6 provided in the pixel driver PXD, and the scan write line GWL, the scan initialization line GIL, the gate control line GCL, and the emission control line ECL that are connected to the gate electrodes G11, G12, G2, G31, G32, G4, G5, and G6 of the first to sixth transistors ST1 to ST6 and extend in the first direction DR1.

The first conductive layer CDL1 may be formed as a single layer or multiple layers including any one of molybdenum (Mo), aluminum (Al), chromium (Cr), gold (Au), titanium (Ti), nickel (Ni), neodymium (Nd) and copper (Cu) or any alloys thereof.

As shown in FIG. 15, the second gate insulating layer 123 may include or consist of an inorganic layer disposed on the first gate insulating layer 122 and covering the first conductive layer CDL1.

In an embodiment, the second gate insulating layer 123 may include or consist of an inorganic layer of a silicon nitride layer, a silicon oxynitride layer, a silicon oxide layer, a titanium oxide layer, or an aluminum oxide layer, for example.

The second conductive layer CDL2 is disposed on the second gate insulating layer 123.

As shown in FIG. 13, the second conductive layer CDL2 may include the shielding electrode SHE, the first power horizontal auxiliary line VDSBL1, the gate initialization voltage line VGIL, and the anode initialization voltage line VAIL.

The second conductive layer CDL2 may be formed as a single layer or multiple layers including any one of molybdenum (Mo), aluminum (Al), chromium (Cr), gold (Au), titanium (Ti), nickel (Ni), neodymium (Nd) and copper (Cu) or any alloys thereof.

As illustrated in FIG. 15, the inter-insulating layer 124 may include or consist of an inorganic layer disposed on the second gate insulating layer 123 and covering the second conductive layer CDL2.

In an embodiment, the inter-insulating layer 124 may include or consist of an inorganic layer of a silicon nitride layer, a silicon oxynitride layer, a silicon oxide layer, a titanium oxide layer, or an aluminum oxide layer, for example.

The third conductive layer CDL3 is disposed on the inter-insulating layer 124.

As shown in FIG. 13, the third conductive layer CDL3 may include the first connection electrode CE1, the second connection electrode CE2, the third connection electrode CE3, the first power vertical auxiliary line VDSBL2, the gate initialization voltage auxiliary line VGIAL, and the anode initialization voltage auxiliary line VAIAL.

Referring to FIGS. 13 and 15, the pixel driver PXD may include the first contact hole CT1, the second contact hole CT2, the third contact hole CT3, the fourth contact hole CT4, the fifth contact hole CT5, the sixth contact hole CT6, and the seventh contact hole CT7.

The first contact hole CT1 is to make connection between the first connection electrode CE1 and the gate electrode GDT of the driving transistor DT.

The first contact hole CT1 may correspond to a portion of the gate electrode GDT of the driving transistor DT and may penetrate the second gate insulating layer 123 and the inter-insulating layer 124. Thus, the first connection electrode CE1 including or consisting of the third conductive layer CDL3 may be electrically connected to the gate electrode GDT of the driving transistor DT including or consisting of the first conductive layer CDL1 through the first contact hole CT1.

The second contact hole CT2 is to make connection between any one of the drain electrode D12 of the second sub-transistor ST12 and the source electrode S31 of the third sub-transistor ST31, and the first connection electrode CE1. The drain electrode D12 of the second sub-transistor ST12 is connected to the source electrode S31 of the third sub-transistor ST31.

The second contact hole CT2 may correspond to a portion of any one of the drain electrode D12 of the second sub-transistor ST12 and the source electrode S31 of the third sub-transistor ST31, and may penetrate the first gate insulating layer 122, the second gate insulating layer 123, and the inter-insulating layer 124. Accordingly, the first connection electrode CE1 including or consisting of the third conductive layer CDL3 may be electrically connected to the drain electrode D12 of the second sub-transistor ST12 and the source electrode S31 of the third sub-transistor ST31 including or consisting of the semiconductor layer SEL through the second contact hole CT2.

In addition, the gate electrode GDT of the driving transistor DT may be electrically connected to the drain electrode D12 of the second sub-transistor ST12 and the source electrode S31 of the third sub-transistor ST31 through the first contact hole CT1, the second contact hole CT2, and the first connection electrode CE1.

The third contact hole CT3 is to make connection between the shielding electrode SHE and the first power vertical auxiliary line VDSBL2.

The third contact hole CT3 may correspond to a part of the first power vertical auxiliary line VDSBL2 and pass through the inter-insulating layer 124. Thus, the shielding electrode SHE including or consisting of the second conductive layer CDL2 may be electrically connected to the first power vertical auxiliary line VDSBL2 including or consisting of the third conductive layer CDL3 through the third contact hole CT3.

The fourth contact hole CT4 is to make connection between the second connection electrode CE2 and the source electrode S2 of the second transistor ST2.

The fourth contact hole CT4 may correspond to a part of the source electrode S2 of the second transistor ST2 and may pass through the first gate insulating layer 122, the second gate insulating layer 123, and the inter-insulating layer 124. Accordingly, the second connection electrode CE2 including or consisting of the third conductive layer CDL3 may be electrically connected to the source electrode S2 of the second transistor ST2 including or consisting of the semiconductor layer SEL through the fourth contact hole CT4.

The fifth contact hole CT5 is to make connection between the first power horizontal auxiliary line VDSBL1 and the first power vertical auxiliary line VDSBL2.

The fifth contact hole CT5 may correspond to a part of the first power horizontal auxiliary line VDSBL1 and may pass through the inter-insulating layer 124. Thus, the first power vertical auxiliary line VDSBL2 including or consisting of the third conductive layer CDL3 may be connected to the first power horizontal auxiliary line VDSBL1 including or consisting of the second conductive layer CDL2 through the fifth contact hole CT5.

The sixth contact hole CT6 is to make connection between the first power vertical auxiliary line VDSBL2 and the source electrode S5 of the fifth transistor ST5.

The sixth contact hole CT6 may correspond to a part of the source electrode S5 of the fifth transistor ST5 and may pass through the first gate insulating layer 122, the second gate insulating layer 123, and the inter-insulating layer 124. Accordingly, the first power vertical auxiliary line VDSBL2 including or consisting of the third conductive layer CDL3 may be electrically connected to the source electrode S5 of the fifth transistor ST5 including or consisting of the semiconductor layer SEL through the sixth contact hole CT6.

The seventh contact hole CT7 is to make connection between the third connection electrode CE3 and the drain electrode D5 of the fifth transistor ST5.

The seventh contact hole CT7 may correspond to a part of the drain electrode D5 of the fifth transistor ST5 and may pass through the first gate insulating layer 122, the second gate insulating layer 123, and the inter-insulating layer 124. Accordingly, the third connection electrode CE3 including or consisting of the third conductive layer CDL3 may be electrically connected to the drain electrode D5 of the fifth transistor ST5 including or consisting of the semiconductor layer SEL through the seventh contact hole CT7.

The third conductive layer CDL3 may have a multilayer structure that includes a metal layer having a relatively low resistance property and metal layers respectively disposed on atop surface and a bottom surface of the metal layer and having an ion diffusion preventing property.

In an embodiment, the third conductive layer CDL3 may have a stacked structure of metal layers, and each of the metal layers of the third conductive layer CDL3 may include or consist of any one of molybdenum (Mo), aluminum (Al), chromium (Cr), gold (Au), titanium (Ti), nickel (Ni), neodymium (Nd), and copper (Cu), for example.

Specifically, the metal layer having a relatively low resistance property may include or consist of any one of aluminum (Al), chromium (Cr), gold (Au), nickel (Ni), neodymium (Nd), and copper (Cu).

The metal layer having an ion diffusion preventing property may include or consist of titanium (Ti).

That is, the third conductive layer CDL3 may have a stacked structure (Ti/Al/Ti) of titanium (Ti)/aluminum (Al)/titanium (Ti).

The first planarization layer 125 covering the third conductive layer CDL3 may include or consist of an organic layer such as acryl resin, epoxy resin, phenolic resin, polyamide resin, polyimide resin or the like.

The fourth conductive layer CDL4 is disposed on the first planarization layer 125.

As shown in FIG. 14, the fourth conductive layer CDL4 may include the first power auxiliary line VDAL, the first dummy line DML1, the fourth connection electrode CE4, and the data connection electrode DCE.

The first dummy line DML1 may include the first transmission detour line TDEL1 and the first auxiliary line ASL2.

The fourth conductive layer CDL4 may be formed as a single layer or multiple layers including any one of molybdenum (Mo), aluminum (Al), chromium (Cr), gold (Au), titanium (Ti), nickel (Ni), neodymium (Nd) and copper (Cu) or any alloys thereof.

Similarly to the third conductive layer CDL3, the fourth conductive layer CDL4 may have a stacked structure of metal layers, and each of the metal layers of the third conductive layer CDL3 may include or consist of any one of molybdenum (Mo), aluminum (Al), chromium (Cr), gold (Au), titanium (Ti), nickel (Ni), neodymium (Nd), and copper (Cu).

That is, the fourth conductive layer CDL4 may have a stacked structure (Ti/Al/Ti) of titanium (Ti)/aluminum (Al)/titanium (Ti).

As shown in FIG. 15, the second planarization layer 126 covering the fourth conductive layer CDL4 may include or consist of an organic layer such as acryl resin, epoxy resin, phenolic resin, polyamide resin, polyimide resin or the like.

Since the fourth conductive layer CDL4 includes the first dummy line DML1 and the second planarization layer 126 covers the fourth conductive layer CDL4, the via layer VIA1 (refer to FIGS. 8 and 9) may include the second planarization layer 126.

The fifth conductive layer CDL5 is disposed on the second planarization layer 126.

As illustrated in FIG. 14, the fifth conductive layer CDL5 may include the data line DL, the second dummy line DML2, and the fifth connection electrode CE5.

The second dummy line DML2 may include the second transmission detour line TDEL2 and the second auxiliary line ASL2.

The fifth conductive layer CDL5 may be formed as a single layer or multiple layers including any one of molybdenum (Mo), aluminum (Al), chromium (Cr), gold (Au), titanium (Ti), nickel (Ni), neodymium (Nd) and copper (Cu) or any alloys thereof.

As shown in FIG. 15, the third planarization layer 127 covering the fifth conductive layer CDL5 may include or consist of an organic layer such as acryl resin, epoxy resin, phenolic resin, polyamide resin, polyimide resin or the like.

The eighth contact hole CT8 is to make connection between the fourth connection electrode CE4 and the third connection electrode CE3.

The eighth contact hole CT8 may correspond to a portion of the third connection electrode CE3, and may penetrate the first planarization layer 125. Accordingly, the fourth connection electrode CE4 including or consisting of the fourth conductive layer CDL4 may be electrically connected to the third connection electrode CE3 including or consisting of the third conductive layer CDL3 through the eighth contact hole CT8.

The ninth contact hole CT9 is to make connection between the fourth connection electrode CE4 and the fifth connection electrode CE5.

The ninth contact hole CT9 may correspond to another portion of the fourth connection electrode CE4 and penetrate the second planarization layer 126. Thus, the fifth connection electrode CE5 including or consisting of the fifth conductive layer CDL5 may be electrically connected to the fourth connection electrode CE4 including or consisting of the fourth conductive layer CDL4 through the ninth contact hole CT9.

The tenth contact hole CT10 is to make connection between a data connection electrode DCE4 and the second connection electrode CE2.

The tenth contact hole CT10 may correspond to a portion of the second connection electrode CE2, and may penetrate the first planarization layer 125. Thus, the data connection electrode DCE4 including or consisting of the fourth conductive layer CDL4 may be electrically connected to the second connection electrode CE2 including or consisting of the third conductive layer CDL3 through the tenth contact hole CT10.

The data connection hole DTCH is to make connection between the data connection electrode DCE4 and the data line DL.

The data connection hole DTCH may correspond to another portion of the data connection electrode DCE4, and may penetrate the second planarization layer 126. Accordingly, the data line DL may be electrically connected to the data connection electrode DCE4 through the data connection hole DTCH.

As illustrated in FIG. 15, the light-emitting element layer 130 may be disposed on the third planarization layer 127 of the circuit layer 120.

In an embodiment, the light-emitting element layer 130 may include the anode electrodes AND disposed on the third planarization layer 127, respectively corresponding to the emission areas EA, and electrically connected to the pixel drivers PXD, respectively, a pixel defining layer PDL disposed on the third planarization layer 127, corresponding to the non-emission area NEA that is a separation region between the emission areas EA, and covering edges of the anode electrodes AND, the light-emitting layers EML respectively corresponding to the emission areas EA and respectively disposed on the anode electrodes AND, and the cathode electrode CTD corresponding to the emission areas EA, disposed on the pixel defining layer PDL and the light-emitting layers EML, and electrically connected to the second power supply line VSSPL, for example.

The anode electrode AND may be connected to the fifth connection electrode CE5 through the anode contact hole ANCT penetrating the third planarization layer 127.

Accordingly, the anode electrode AND may be electrically connected to the fourth transistor ST4 and the sixth transistor ST6 through the seventh contact hole CT7, the third connection electrode CE3, the eighth contact hole CTB, the fourth connection electrode CE4, the ninth contact hole CT9, the fifth connection electrode CE5, and the anode contact hole ANCT.

The pixel defining layer PDL may include or consist of an organic layer.

The light-emitting layer EML may include an organic light-emitting material.

Although not separately shown, a first common layer (not shown) including at least a hole transport material may be disposed between the anode electrode AND and the light-emitting layer EML.

A second common layer (not shown) including at least an electron transport material may be disposed between the light-emitting layer EML and the cathode electrode CTD.

The cathode electrode CTD may correspond to the display area DA.

Although not separately shown, the cathode electrode CTD may be electrically connected to the second power supply line VSSPL in the non-display area NDA.

Accordingly, the light-emitting element layer 130 may include the light-emitting elements LEL which respectively correspond to the emission areas EA and each of which has a structure including the anode electrode AND and the cathode electrode CTD facing each other and the light-emitting layer EML interposed therebetween.

The light-emitting element layer 130 may be covered with the encapsulation layer 140 to block penetration of oxygen or moisture.

The encapsulation layer 140 may cover the light-emitting element layer 130 and may have a structure in which at least one inorganic layer and at least one organic layer are cross-stacked.

In an embodiment, the encapsulation layer 140 may include a first inorganic layer 141, which includes or consists of an inorganic insulating material, covers the cathode electrode CTD, and contacts the inter-insulating layer 124 in the non-display area NDA, an organic layer 142, which includes or consists of an organic insulating material, is disposed on the first inorganic layer 141, and corresponds to the display area DA, and a second inorganic layer 143 which includes or consists of an inorganic insulating material, covers the organic layer 142, and contacts the first inorganic layer 141 in the non-display area NDA, for example.

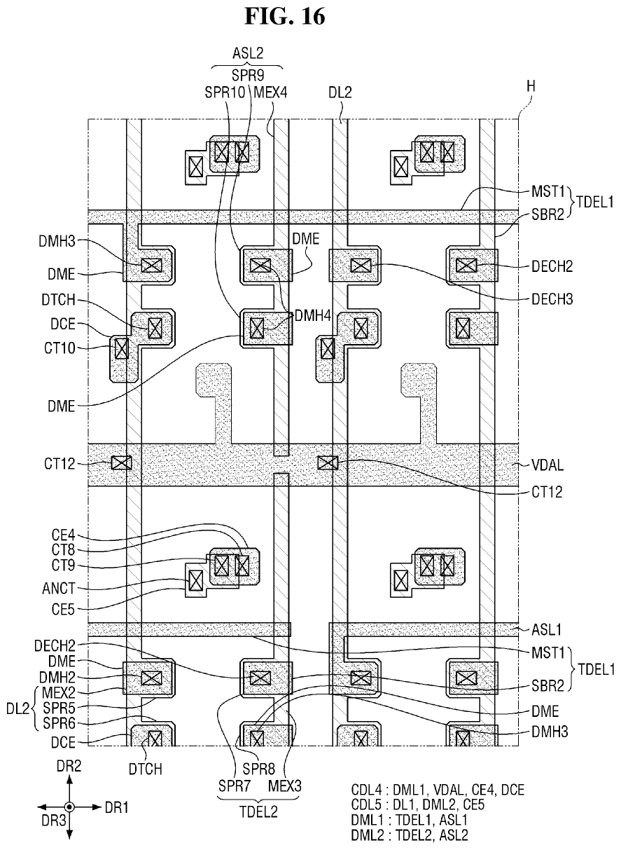

FIG. 16 is a plan view showing a fourth conductive layer and a fifth conductive layer in part H of FIG. 5 according to the first embodiment.

FIG. 16 is a plan view showing two pixel drivers PXD disposed in the second detour side area SDA2 and adjacent to each other in the first direction DR1.

Referring to FIG. 16, the second data line DL2 may include the second main extension MEX2 extending in the second direction DR2, and the fifth sub-protrusion SPR5 and the sixth sub-protrusion SPR6 protruding from the second main extension MEX2.

The fifth sub-protrusion SPR5 may overlap the second dummy hole DMH2 and the dummy electrode DME that are irrelevant to the electrical connection.

The sixth sub-protrusion SPR6 may overlap the data connection electrode DCE and the data connection hole DTCH of the pixel drivers PXD.

The second transmission detour line TDEL2 adjacent to the second data line DL2 may include the third main extension MEX3, and the seventh sub-protrusion SPR7 and the eighth sub-protrusion SPR8 protruding from the third main extension MEX3 and respectively facing the fifth sub-protrusion SPR5 and the sixth sub-protrusion SPR6 of the second data line DL2.

The seventh sub-protrusion SPR7 may overlap the second sub-branch SBR2 of the first transmission detour line TDEL1.

The second detour connection hole DECH2 for electrical connection between the first transmission detour line TDEL1 and the second transmission detour line TDEL2 may overlap the second sub-branch SBR2 and the seventh sub-protrusion SPR7.

The eighth sub-protrusion SPR8 may overlap the third dummy hole DMH3 and the dummy electrode DME that are irrelevant to the electrical connection.

As shown in FIG. 16, the pixel drivers PXD of the second detour side area SDA2 are substantially the same as the pixel drivers of the first detour side area SDA1 shown in FIG. 14 except that the components provided as the fifth conductive layer CDL5 are not the first data line DL1 and the second auxiliary line ASL2 but the second data line DL2, the second transmission detour line TDEL2, and the second auxiliary line ASL2, so that the redundant description thereof will be omitted.

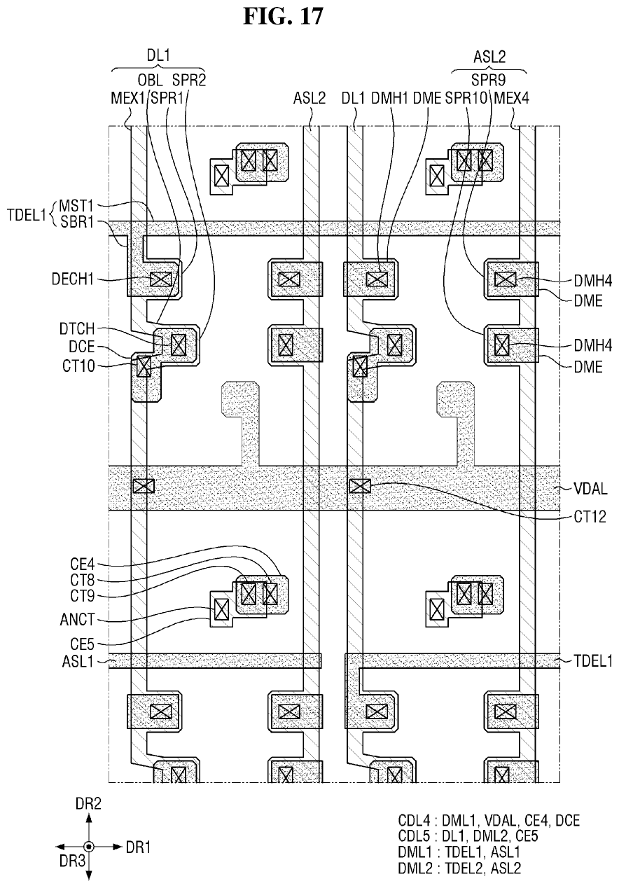

FIG. 17 is a plan view showing a fourth conductive layer and a fifth conductive layer in part G of FIG. 5 according to a second embodiment.

Referring to FIG. 17, the display device 10 according to the second embodiment is substantially the same as the display device according to the first embodiment of FIG. 14 except that the first data line DL1 of the circuit layer 120 includes an oblique portion OBL that connects the first main extension MEX1 and the second sub-protrusion SPR2 and extends in a predetermined diagonal direction intersecting the first direction DR1 and the second direction DR2, so that the redundant description thereof will be omitted below.

The oblique portions OBL may connect opposite sides of the second sub-protrusion SPR2 in the second direction DR2 to the first main extension MEX1.

As described above, in accordance with the second embodiment, the first data line DL1 includes the oblique portion OBL, so that the width of the overlapping area between each of the second connection electrode CE2 and the data connection electrode DCE and the first data line DL1 may be reduced. Therefore, an unnecessary parasitic capacitance may be prevented, and malfunction of the pixel driver PXD may be prevented.

Since the second data line DL2 and the third data line DL3 according to the second embodiment are substantially the same as the first data line DL1 of FIG. 17, the redundant description thereof will be omitted below.

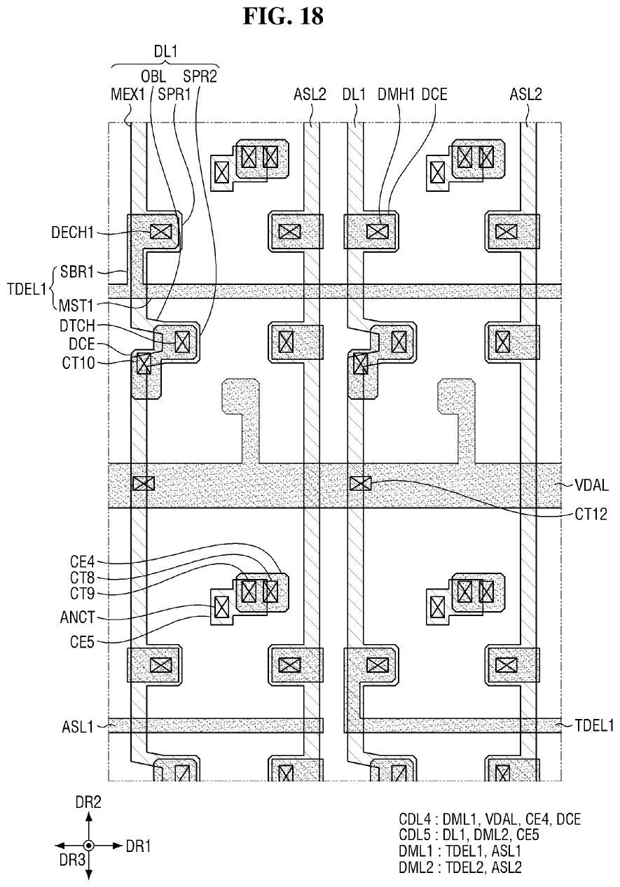

FIG. 18 is a plan view showing a fourth conductive layer and a fifth conductive layer in part G of FIG. 5 according to a third embodiment.

Referring to FIG. 18, the display device 10 according to the third embodiment is substantially the same as the display device according to the second embodiment of FIG. 17 except that the first main stream MST1 of the first transmission detour line TDEL1 of the circuit layer 120 is spaced part from each of the first sub-protrusion SPR1 and the second sub-protrusion SPR2 of the first data line DL1 and is disposed between the first sub-protrusion SPR1 and the second sub-protrusion SPR2 of the first data line DL1 in the second direction DR2, so that the redundant description thereof will be omitted below.

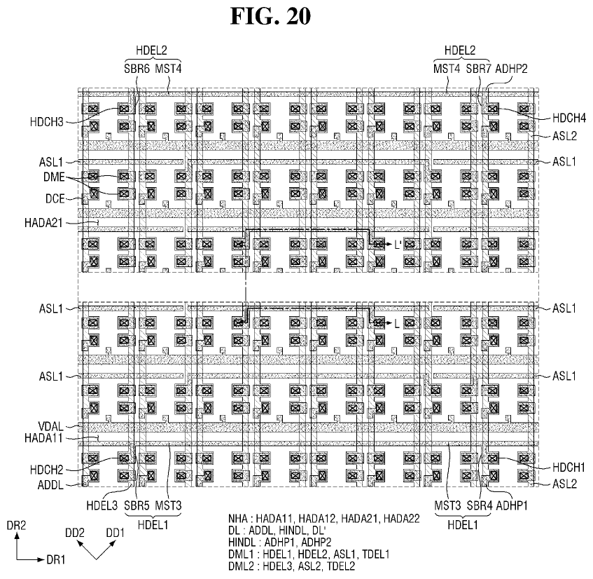

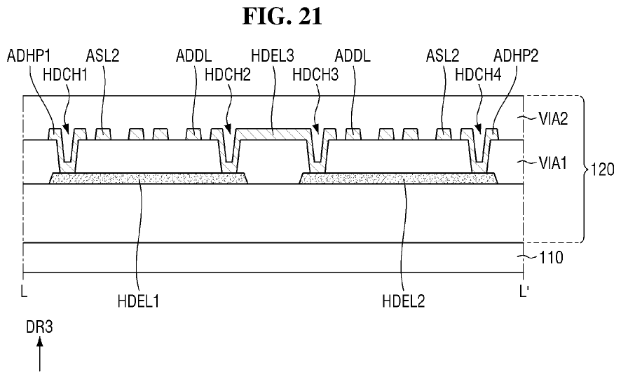

FIG. 19 is a layout diagram showing part F of FIG. 4 according to a fourth embodiment. FIG. 20 is a layout diagram showing data lines, first dummy lines, and second dummy lines in a part of each of a first hole vicinity side area and a second hole vicinity side area of FIG. 19. FIG. 21 is a cross-sectional view showing a plane taken along line L-L′ of FIG. 21.

The main area MA of the display device 10 according to the fourth embodiment may include a hole area HLA surrounded by the display area DA.

Referring to FIG. 19, the substrate 110 of the display panel 100 of the display device 10 according to the fourth embodiment may further include a through portion THM disposed in the hole area HLA and penetrating the display panel 100.

The display panel 100 of the display device 10 may further include a through portion vicinity sealing portion (not shown) disposed between the through portion THM and the display area DA in the hole area HLA.

The through portion THM may overlap at least a part of a functional module (not shown) disposed outside the display panel 100, and may be provided as a path for inputting sensing information of the functional module or a path for outputting sound of the functional module.

In an embodiment, the functional module may be disposed to overlap the through portion THM and its vicinity on the rear surface of the display panel 100, or may be disposed in the through portion THM, for example.

In an embodiment, the functional module may include a camera module for imaging or recognizing an image corresponding to the front surface of the display device 10, a face recognition sensor module for detecting a user's face, a pupil recognition sensor module for detecting a user's pupil, an acceleration sensor module and a geomagnetic sensor module for determining the movement of the display device, a proximity sensor module and an infrared sensor module for detecting whether the front surface of the display device 10 is close, and an illuminance sensor module for measuring a degree of external brightness, or the like, for example.

Since the display device 10 includes the hole area HLA, the display area DA may include a hole vicinity area NHA where detour lines for electrical connection of lines separated by the hole area HLA are disposed.

The data lines DL of the circuit layer 120 may include a hole intersection data line HINDL intersecting the hole area HLA, an adjacent data line ADDL disposed in the hole vicinity area NHA, and other data lines DL′.

The other data lines DL′ may include the first data line DL1, the second data line DL2, and the third data line DL3 shown in FIG. 6.

The hole intersection data line HINDL is separated by the hole area HLA, and thus may include a first hole adjacent portion ADHP1 and a second hole adjacent portion ADHP2 spaced apart from each other in the second direction DR2.

The first hole adjacent portion ADHP1 may be disposed adjacent to one side (lower side of FIG. 20) of the hole area HLA in the second direction DR2.

The second hole adjacent portion ADHP2 may be disposed adjacent to an opposite side (upper side of FIG. 20) of the hole area HLA in the second direction DR2.

Since the first hole adjacent portion ADHP1 and the second hole adjacent portion ADHP2 are spaced apart from each other, the circuit layer 120 of the display device 10 according to the fourth embodiment may further include a first hole detour line HDEL1, a second hole detour line HDEL2, and a third hole detour line HDEL3 that are provided for electrical connection between the first hole adjacent portion ADHP1 and the second hole adjacent portion ADHP2.

The first hole detour line HDEL1, the second hole detour line HDEL2, and the third hole detour line HDEL3 may be disposed in the hole vicinity area NHA disposed around the hole area HLA in the display area DA.

In accordance with the fourth embodiment, the first dummy lines DML1 of the circuit layer 120 may further include the first hole detour line HDEL1 electrically connected to the first hole adjacent portion ADHP1 of the hole intersection data line HINDL, and the second hole detour line HDEL2 electrically connected to the second hole adjacent portion ADHP2 of the hole intersection data line HINDL.

Further, the second dummy lines DML2 of the circuit layer 120 may further include the third hole detour line HDEL3 that electrically connects the first hole detour line HDEL1 to the second hole detour line HDEL2.

The hole vicinity area NHA may be separated by an imaginary line in the first direction DR1 and an imaginary line in the second direction DR2 with respect to a midpoint THC of the hole area HLA. Accordingly, the hole vicinity area NHA may be divided into a first hole adjacent area HADA11 and a second hole adjacent area HADA12 that contact one side (left side of FIG. 19) of the hole area HLA in the first direction DR1 and adjacent to each other in the second direction DR2, and a third hole adjacent area HADA21 and a fourth hole adjacent area HADA22 that contact an opposite side (right side of FIG. 19) of the hole area HLA in the first direction DR1 and adjacent to the first hole adjacent area HADA11 and the second hole adjacent area HADA12 in the first direction DR1.

The first hole adjacent portion ADHP1 and the second hole adjacent portion ADHP2 respectively disposed in the first hole adjacent area HADA11 and the second hole adjacent area HADA12 may be electrically connected to each other by the first hole detour line HDEL1, the second hole detour line HDEL2, and the third hole detour line HDEL3 that are disposed in the first hole adjacent area HADA11 and the second hole adjacent area HADA12.

Similarly, the first hole adjacent portion ADHP1 and the second hole adjacent portion ADHP2 respectively disposed in the third hole adjacent area HADA21 and the fourth hole adjacent area HADA22 may be electrically connected to each other by the first hole detour line HDEL1, the second hole detour line HDEL2, and the third hole detour line HDEL3 that are disposed in the third hole adjacent area HADA21 and the fourth hole adjacent area HADA22.

A part of the hole vicinity area NHA may be included in the display area DA, and the other part thereof may be included in the non-display area NDA.

The hole intersection data line HINDL may be adjacent to the second auxiliary line ASL2.

The first hole detour line HDEL1 may extend in the first direction DR1 between the first hole adjacent portion ADHP1 and the third hole detour line HDEL3.

The second hole detour line HDEL2 may extend in the first direction DR1 between the second hole adjacent portion ADHP2 and the third hole detour line HDEL3.

The third hole detour line HDEL3 may be adjacent to the adjacent data line ADDL, and may extend in the second direction DR2 between the first hole detour line HDEL1 and the second hole detour line HDEL2.

Referring to FIG. 20, the first hole detour line HDEL1 may include a third main stream MST3 extending in the first direction DR1 between the first hole adjacent portion ADHP1 and the third hole detour line HDEL3, a fourth sub-branch SBR4 extending from the third main stream MST3 in the second direction DR2 and overlapping a part of the first hole adjacent portion ADHP1, and a fifth sub branch SBR5 extending from the third main stream MST3 in the second direction DR2 and overlapping a part of the third hole detour line HDEL3.

The second hole detour line HDEL2 may include a fourth main stream MST4 extending in the first direction DR1 between the second hole adjacent portion ADHP2 and the third hole detour line HDEL3, a sixth sub-branch SBR6 extending from the fourth main stream MST4 in the second direction DR2 and overlapping a part of the third hole detour line HDEL3, and a seventh sub-branch SBR7 extending from the third main stream MST3 in the second direction DR2 and overlapping a part of the second hole adjacent portion ADHP2.

The first hole detour line HDEL1 may be electrically connected to the first hole adjacent portion ADHP1 through a first hole detour connection hole HD CH1 defined in the overlapping area between the fourth sub-branch SBR4 and one sub-protrusion of the first hole adjacent portion ADHP1.

The first hole detour line HDEL1 may be electrically connected to the third hole detour line HDEL3 through a second hole detour connection hole HDCH2 defined in the overlapping area between the fifth sub-branch SBR5 and one sub-protrusion of the third hole detour line HDEL3.

Accordingly, the first hole adjacent portion ADHP1 may be electrically connected to the third hole detour line HDEL3 through the first hole detour line HDEL1.

The second hole detour line HDEL2 may be electrically connected to the third hole detour line HDEL3 through a third hole detour connection hole HDCH3 defined in the overlapping area between the sixth sub branch SBR6 and another sub-protrusion of the third hole detour line HDEL3.

The second hole detour line HDEL2 may be electrically connected to the second hole adjacent portion ADHP2 through a fourth hole detour connection hole HDCH4 defined in the overlapping area between the seventh sub-branch SBR7 and one sub-protrusion of the second hole adjacent portion ADHP2.

Accordingly, the second hole adjacent portion ADHP2 may be electrically connected to the third hole detour line HDEL3 through the second hole detour line HDEL2.

Therefore, the first hole adjacent portion ADHP1 and the second hole adjacent portion ADHP2 of the hole intersection data line HINDL may be electrically connected to each other through the first hole detour line HDEL1, the second hole detour line HDEL2, and the third hole detour line HDEL3.

Referring to FIG. 21, each of the first hole detour connection hole HDCH1, the second hole detour connection hole HDCH2, the third hole detour connection hole HDCH3, and the fourth hole detour connection hole HDCH4 may penetrate the via layer VIAL

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate comprising a main region comprising:
a display area in which emission areas are arranged; and
a non-display area disposed around the display area;
a circuit layer disposed on the substrate; and
a light-emitting element layer disposed on the circuit layer and comprising light-emitting elements respectively corresponding to the emission areas,
wherein a detour area on a side of the display area comprises:
a detour middle area at a center;
a first detour side area parallel to the detour middle area in a first direction and in contact with the non-display area; and
a second detour side area disposed between the detour middle area and the first detour side area,
the circuit layer comprises:
pixel drivers corresponding to the emission areas and electrically connected to the light-emitting elements of the light-emitting element layer, respectively;
data lines which extend in a second direction crossing the first direction and transmit data signals to the pixel drivers;
a first transmission detour line electrically connected to, among the data lines, a first data line disposed in the first detour side area and extending in the first direction; and
a second transmission detour line adjacent to, among the data lines, a second data line disposed in the second detour side area, extending in the second direction, and electrically connected to the first transmission detour line, and
the first transmission detour line comprises:
a first main stream extending in the first direction between the first data line and the second transmission detour line;
a first sub-branch disposed in the first detour side area, extending in the second direction from the first main stream, and overlapping a part of the first data line; and
a second sub-branch disposed in the second detour side area, extending in the second direction from the first main stream, and overlapping a part of the second transmission detour line.

2. The display device of claim 1, wherein each of the pixel drivers comprises a data connection electrode electrically connected to one of the data lines through a data connection hole,
the pixel drivers comprise a first pixel driver adjacent to the first sub-branch of the first transmission detour line,
the first data line comprises:
a first main extension extending in the second direction;
a first sub-protrusion adjacent to the first pixel driver, protruding from the first main extension and overlapping the first sub-branch; and
a second sub-protrusion adjacent to the first pixel driver, protruding from the first main extension and overlapping the data connection hole of the first pixel driver,
the first transmission detour line is electrically connected to the first data line through a first detour connection hole overlapping the first sub-branch and the first sub-protrusion, and
the first detour connection hole is spaced apart from an intersection between the first main stream of the first transmission detour line and the first main extension of the first data line.

3. The display device of claim 2, wherein the pixel drivers further comprise a second pixel driver disposed in the first detour side area, electrically connected to the first data line, and spaced apart from the first pixel driver,
the first data line further comprises a third sub-protrusion and a fourth sub-protrusion adjacent to the second pixel driver and protruding from the first main extension,
the third sub-protrusion overlaps a first dummy hole, and
the fourth sub-protrusion overlaps the data connection electrode of the second pixel driver.

4. The display device of claim 3, wherein the data lines and the second transmission detour line are disposed on a via layer covering the first transmission detour line and the data connection electrode, and
the first detour connection hole, a second detour connection hole, and the first dummy hole penetrate the via layer.

5. The display device of claim 4, wherein the first dummy hole overlaps a dummy electrode covered with the via layer.

6. The display device of claim 4, wherein the pixel drivers further comprise a third pixel driver disposed in the second detour side area, adjacent to the second sub-branch of the first transmission detour line, electrically connected to the second data line, and disposed parallel to the first pixel driver in the first direction, and
the second data line comprises:
a second main extension extending in the second direction;
a fifth sub-protrusion adjacent to the third pixel driver, protruding from the second main extension, and disposed parallel to the first sub-protrusion of the first data line in the first direction; and
a sixth sub-protrusion adjacent to the third pixel driver, protruding from the second main extension, disposed parallel to the second sub-protrusion of the first data line in the first direction, and overlapping the data connection electrode of the third pixel driver, and
The fifth sub-protrusion overlaps a second dummy hole penetrating the via layer.

7. The display device of claim 6, wherein the second transmission detour line comprises:
a third main extension extending in the second direction;
a seventh sub-protrusion adjacent to the third pixel driver, protruding from the third main extension, facing the fifth sub-protrusion of the second data line, and overlapping the second sub-branch; and
an eighth sub-protrusion adjacent to the third pixel driver, protruding from the third main extension, and facing the sixth sub-protrusion of the second data line,
wherein the first transmission detour line is electrically connected to the second transmission detour line through a second detour connection hole overlapping the second sub-branch and the seventh sub-protrusion, and
the eighth sub-protrusion overlaps a third dummy hole penetrating the via layer.

8. The display device of claim 7, wherein the circuit layer further comprises:
a first power supply line and a second power supply line which are disposed in the non-display area and respectively transmit a first power and a second power for driving the light-emitting elements;
first power auxiliary lines disposed in the display area, extending in the first direction, and electrically connected to the first power supply line;
first dummy lines respectively adjacent to the first power auxiliary lines and extending in the first direction; and
second dummy lines respectively adjacent to the data lines and extending in the second direction,
wherein the first dummy lines comprise first auxiliary lines electrically connected to the second power supply line, and the first transmission detour line,
the second dummy lines comprise second auxiliary lines electrically connected to the second power supply line, and the second transmission detour line,
one of the first auxiliary lines comprises:
a second main stream extending in the first direction; and
a third sub-branch extending from the second main stream in the second direction,
each of the second auxiliary lines comprises:
a fourth main extension extending in the second direction; and
ninth sub-protrusions and a tenth sub-protrusion protruding from the fourth main extension to each of the pixel drivers,
wherein some of the ninth sub-protrusions of the second auxiliary lines overlap the third sub-branch,
remaining ones of the ninth sub-protrusions of the second auxiliary lines and the tenth sub-protrusion of the second auxiliary lines overlap a fourth dummy hole penetrating the via layer, and
the first auxiliary lines are electrically connected to the second auxiliary lines through an auxiliary connection hole overlapping the third sub-branch and the ninth sub-protrusions.

9. The display device of claim 8, wherein the first dummy hole, the second dummy hole, the third dummy hole, and the fourth dummy hole overlap dummy electrodes covered with the via layer, respectively.

10. The display device of claim 9, wherein the circuit layer has a structure comprising:
a semiconductor layer on the substrate;
a first conductive layer on a first gate insulating layer covering the semiconductor layer;
a second conductive layer on a second gate insulating layer covering the first conductive layer;
a third conductive layer on an inter-insulating layer covering the second conductive layer;
a fourth conductive layer on a first planarization layer covering the third conductive layer;
a fifth conductive layer on a second planarization layer covering the fourth conductive layer; and
a third planarization layer covering the fifth conductive layer,
the fourth conductive layer comprises the first power auxiliary lines, the first dummy lines, and the dummy electrodes,
the fifth conductive layer comprises the data lines and the second dummy lines, and
the via layer comprises the second planarization layer.

11. The display device of claim 8, wherein the substrate further comprises a hole area surrounded by the display area,
the data lines further comprise a hole intersection data line intersecting the hole area,
the hole intersection data line comprises a first hole adjacent portion disposed adjacent to a side of the hole area in the second direction, and a second hole adjacent portion disposed adjacent to an opposite side of the hole area in the second direction,
the first dummy lines further comprise:
a first hole detour line electrically connected to the first hole adjacent portion of the hole intersection data line; and
a second hole detour line electrically connected to the second hole adjacent portion of the hole intersection data line, and
the second dummy lines further comprise a third hole detour line electrically connecting the first hole detour line and the second transmission detour line, and
the first hole detour line comprises:
a third main stream extending in the first direction between the first hole adjacent portion and the third hole detour line;
a fourth sub-branch extending from the third main stream in the second direction and overlapping a part of the first hole adjacent portion; and
a fifth sub-branch extending from the third main stream in the second direction and overlapping a part of the third hole detour line.

12. The display device of claim 11, wherein the second hole detour line comprises:
a fourth main stream extending in the first direction between the second hole adjacent portion and the third hole detour line;
a sixth sub-branch extending from the fourth main stream in the second direction and overlapping a part of the third hole detour line; and
a seventh sub-branch extending from the fourth main stream in the second direction and overlapping a part of the second hole adjacent portion.

13. The display device of claim 4, further comprising a display driving circuit disposed in a sub-region protruding in the second direction from a side of the main region of the substrate and outputting a data signal of each of the data lines,
wherein the circuit layer further comprises data supply lines which are disposed in the non-display area and the sub-region, electrically connected to output terminals of the display driving circuit, respectively, and transmit the data signal of each of the data lines to the display area,
among the data supply lines, a first data supply line which transmits a data signal of the first data line is connected to the second transmission detour line, and
among the data supply lines, a second data supply line which transmits a data signal of the second data line is connected to the second data line.

14. The display device of claim 4, wherein the first main stream of the first transmission detour line is disposed closer to the first sub-protrusion, between the first sub-protrusion and the second sub-protrusion of the first data line, in the second direction.

15. The display device of claim 4, wherein the first main stream of the first transmission detour line is disposed between the first sub-protrusion and the second sub-protrusion of the first data line in the second direction.

16. A display device comprising:
a substrate comprising:
a main region comprising a display area in which emission areas are arranged and a non-display area disposed around the display area; and
a sub-region protruding from a side of the main region;
a circuit layer disposed on the substrate and comprising pixel drivers respectively corresponding to the emission areas; and
a light-emitting element layer disposed on the circuit layer and comprising light-emitting elements respectively corresponding to the emission areas,
wherein the circuit layer comprises:
the pixel drivers respectively and electrically connected to the light-emitting elements of the light-emitting element layer;
data lines which transmit data signals to the pixel drivers;
first dummy lines extending in a first direction crossing the data lines; and
second dummy lines extending in a second direction parallel to the data lines and respectively adjacent to the data lines,
The data lines and the second dummy lines are disposed on a via layer covering the first dummy lines,
one of the pixel drivers is adjacent to one of the data lines and one of the second dummy lines,
each of the one of the data lines and the one of the second dummy lines comprises:
a main extension extending in the second direction; and
a pair of sub-protrusions protruding from the main extension, adjacent to the one of the pixel drivers, and overlapping via holes penetrating the via layer.

17. The display device of claim 16, wherein in the display area, a detour area adjacent to the sub-region comprises a detour middle area disposed at a center in the first direction, a first detour side area parallel to the detour middle area in the first direction and in contact with the non-display area, and a second detour side area disposed between the detour middle area and the first detour side area,
the data lines comprise a first data line disposed in the first detour side area and a second data line disposed in the second detour side area,
the first dummy lines comprise a first transmission detour line electrically connected to the first data line,
the second dummy lines comprise a second transmission detour line adjacent to the second data line and electrically connected to the first transmission detour line, and
the first transmission detour line comprises:
a first main stream extending in the first direction between the first data line and the second transmission detour line;
a first sub-branch disposed in the first detour side area, extending in the second direction from the first main stream, and overlapping a part of the first data line; and
a second sub-branch disposed in the second detour side area, extending in the second direction from the first main stream, and overlapping a part of the second transmission detour line.

18. The display device of claim 17, wherein the circuit layer further comprises:
a first power supply line and a second power supply line which are disposed in the non-display area and respectively transmit a first power and a second power for driving the light-emitting elements; and
first power auxiliary lines disposed in the display area, extending in the first direction, respectively adjacent to the first dummy lines, and electrically connected to the first power supply line,
the first dummy lines comprise first auxiliary lines electrically connected to the second power supply line, and the first transmission detour line,
the second dummy lines comprise second auxiliary lines electrically connected to the second power supply line, and the second transmission detour line, and
one of the first auxiliary lines comprises:
a second main stream extending in the first direction; and
a third sub-branch extending from the second main stream in the second direction and overlapping a part of one of the second auxiliary lines.

19. The display device of claim 18, wherein each of the pixel drivers includes a data connection electrode electrically connected to one of the data lines through a data connection hole, and
among the via holes, remaining via holes except some of the via holes overlapping the data connection electrode, the first sub-branch, the second sub-branch, and the third sub-branch overlap dummy electrodes covered with the via layer, respectively.

20. The display device of claim 19, wherein the substrate further comprises a hole area surrounded by the display area,
the data lines further comprise a hole intersection data line intersecting the hole area,
the hole intersection data line comprises:
a first hole adjacent portion disposed adjacent to a side of the hole area in the second direction; and
a second hole adjacent portion disposed adjacent to an opposite side of the hole area in the second direction,
the first dummy lines further comprise:
a first hole detour line electrically connected to the first hole adjacent portion of the hole intersection data line; and
a second hole detour line electrically connected to the second hole adjacent portion of the hole intersection data line,
the second dummy lines further comprise a third hole detour line electrically connecting the first hole detour line and the second transmission detour line, and
the first hole detour line comprises:
a third main stream extending in the first direction between the first hole adjacent portion and the third hole detour line;
a fourth sub-branch extending from the third main stream in the second direction and overlapping a part of the first hole adjacent portion; and
a fifth sub-branch extending from the third main stream in the second direction and overlapping a part of the third hole detour line.

21. The display device of claim 20, wherein the second hole detour line comprises:
a fourth main stream extending in the first direction between the second hole adjacent portion and the third hole detour line;
a sixth sub-branch extending from the fourth main stream in the second direction and overlapping a part of the third hole detour line; and
a seventh sub-branch extending from the fourth main stream in the second direction and overlapping a part of the second hole adjacent portion.

22. The display device of claim 19, wherein the pair of sub-protrusions includes a first sub-protrusion and a second sub-protrusion, and
the first main stream of the first transmission detour line is disposed closer to the first sub-protrusion, between the first sub-protrusion and the second sub-protrusion of the first data line, in the second direction.

23. The display device of claim 19, wherein the pair of sub-protrusions includes a first sub-protrusion and a second sub-protrusion, and
the first main stream of the first transmission detour line is disposed between the first sub-protrusion and the second sub-protrusion of the first data line in the second direction.
